(19) United States
(12) Patent Application Publication
(10) Pub. No.: US 2013/0009139 A1
(43) Pub. Date: Jan. 10, 2013

(54) Light-Emitting Element, Light-Emitting Device, Display Device, Lighting Device, and Electonic Device

(75) Inventors: Nobuharu Ohsawa, Tochigi (JP); Hiroshi Kadoma, Samigahara (JP)

(73) Assignee: Semiconductor Energy Laboratory Co., Ltd.

(21) Appl. No.: 13/541,373

(22) Filed: Jul. 3, 2012

(30) Foreign Application Priority Data
Jul. 6, 2011 (JP) 2011-149643

(51) Int. Cl. H01L 51/54

(52) U.S. Cl. 257/40; 257/E51.026

(57) ABSTRACT

A light-emitting element is disclosed where a host material and a hole-transport material each consist of a carbazole skeleton and another skeleton other than the carbazole skeleton. Both the highest occupied molecular orbital (HOMO) and the lowest unoccupied molecular orbital (LUMO) of the hole-transport material are distributed over the carbazole skeleton, while the HOMO of the host material is distributed over the carbazole skeleton and the LUMO thereof is distributed over the skeleton other than the carbazole skeleton. This combination of the hole-transport material and the host material allows the fabrication of a light-emitting element with high emission efficiency and low driving voltage.

### BACKGROUND OF THE INVENTION

1. Field of the Invention

The present invention relates to a light-emitting element which includes a light-emitting layer containing an organic compound between a pair of electrodes, and a light-emitting device, a display device, a lighting device, and an electronic device each including the light-emitting element.

2. Description of the Related Art

In recent years, a light-emitting element (also referred to as electroluminescent (EL) element) in which a light-emitting layer (hereinafter also referred to as EL layer) containing an organic compound is interposed between a pair of electrodes has been actively developed. Such a light-emitting element has a wide range of applications such as a display device, a lighting device, and a light source of an electronic device. The reason for this is that an EL element has many advantages; for example, an EL element can respond to an input at high speed, can be fabricated thin and light, and can provide planar light emission.

In addition, an EL element has attracted attention also in terms of its high efficiency of conversion of power into light and its high potential for saving energy. It is also a unique feature of an EL element that, depending on a substrate selected, it is possible to provide a display device or a lighting device which has flexibility, a display device or a lighting device which has high resistance against an impact of physical destruction, or a very lightweight display or lighting device.

In these days of energy problems becoming more serious, importance of a reduction in power consumption of such display devices or lighting devices increases. According to Patent Document 1, a light-emitting element with high emission efficiency can be achieved by providing a hole-transport layer containing a specific material together with a light-emitting layer containing a specific host material.

### REFERENCE

### Patent Document

[Patent Document 1] Japanese Published Patent Application No. 2009-010364

### SUMMARY OF THE INVENTION

As a way of obtaining an organic light-emitting element with high emission efficiency, the use of a phosphorescent emission substance as an emission center substance (guest) can be given.

However, an energy level with which phosphorescence is emitted, a triplet level, is located lower than a singlet level with which fluorescence is emitted in terms of energy. Therefore, for a phosphorescent light-emitting element to obtain light having the same wavelength as a fluorescent light-emitting element, the phosphorescent light-emitting element needs a host material and a carrier-transport material which have a wider energy gap. However, such materials have not well developed as compared to other materials.

Moreover, even with such a material with a wide energy gap, inherent emission efficiency of a phosphorescent element cannot be always achieved, and driving voltage increases in some cases depending on a combination of materials used in the layers.

In view of the above problems, an object of the present invention is to provide a light-emitting element with high emission efficiency. Another object of the invention is to provide a light-emitting element with lower driving voltage. A further object is to provide a light-emitting element, a light-emitting device, a display device, a lighting device, and an electronic device with low power consumption.

The present invention achieves at least one of the above objects.

The present inventors found that the above object can be achieved with the use of a light-emitting element where a host material and a hole-transport material which are different from each other include carbazole skeletons, both the highest occupied molecular orbital (HOMO) and the lowest unoccupied molecular orbital (LUMO) of the hole-transport material are distributed over the carbazole skeleton, and the HOMO of the host material is distributed over the carbazole skeleton and the LUMO thereof is distributed over a skeleton other than the carbazole skeleton. Note that, in the specification, “the HOMO is distributed over a skeleton” means that the HOMO is more widely spread over the skeleton than over other skeletons. Similarly, “the LUMO is distributed over a skeleton” means that the LUMO is more widely spread over the skeleton than over other skeletons.

In other words, one embodiment of the present invention is a light-emitting element having the following structure. The light-emitting element includes an anode, a cathode, and an EL layer provided between the anode and the cathode. The EL layer at least includes a light-emitting layer including an emission center substance and a host material in which the emission center substance is dispersed; and a hole-transport layer provided in contact with the anode side of the light-emitting layer and including a hole-transport material. The hole-transport material is a first carbazole derivative consisting of a carbazole skeleton and a skeleton other than the carbazole skeleton, and the host material is a second carbazole derivative consisting of a carbazole skeleton and a skeleton other than the carbazole skeleton. The HOMO and LUMO of the first carbazole derivative are distributed over the carbazole skeleton. The HOMO of the second carbazole derivative is distributed over the carbazole skeleton and the LUMO of the second carbazole derivative is distributed over the skeleton other than the carbazole skeleton.

Another embodiment of the present invention is a light-emitting element having the above structure in which the first carbazole derivative is an N-phenyl carbazole derivative.

A further embodiment of the present invention is a light-emitting element having the above structure in which the skeleton other than the carbazole skeleton of the second carbazole derivative has a skeleton having an electron-transport property.

A still further embodiment of the present invention is a light-emitting element having the above structure in which the second carbazole derivative is a carbazole derivative having an aryl group.

A yet still further embodiment of the present invention is a light-emitting element having the above structure in which the second carbazole derivative is a carbazole derivative having a heteroaryl group.

A yet still further embodiment of the present invention is a light-emitting element having the above structure in which the first carbazole derivative is 9,9′-(1,3-phenylene)bis(9H-carbazole) (abbreviation: mCP) and the second carbazole derivative is 9,9′-(3′,5′-diphenyl-1,1′-biphenyl-3,5-diyl)bis(9H-carbazole) (abbreviation: mTPmCP).

A yet still further embodiment of the present invention is a light-emitting element having the above structure in which light emitted from the emission center substance is blue fluorescence.

A yet still further embodiment of the present invention is a light-emitting element having the above structure in which light emitted from the emission center substance is phosphorescence having a shorter wavelength than blue-green light.

A yet still further embodiment of the present invention is a light-emitting device including any of the above light-emitting elements as a light source.

A yet still further embodiment of the present invention is a display device including any of the above light-emitting elements in a display portion.

A yet still further embodiment of the present invention is a lighting device including any of the above light-emitting elements as a light source.

A yet still further embodiment of the present invention is an electronic device including any of the above light-emitting elements.

The light-emitting element of one embodiment of the present invention can achieve high emission efficiency. Further, the light-emitting element of one embodiment of the present invention is a light-emitting element with lower driving voltage. In addition, according to one embodiment of the present invention, a light-emitting element, a light-emitting device, a display device, a lighting device, and an electronic device with low power consumption are provided.

### BRIEF DESCRIPTION OF THE DRAWINGS

FIGS. 1A and 1B are conceptual diagrams of light-emitting elements.

FIGS. 2A and 2B are conceptual diagrams of an active matrix light-emitting device.

FIGS. 3A and 3B are conceptual diagrams of a passive matrix light-emitting device.

FIGS. 4A to 4D each illustrate an electronic device.

FIG. 5 illustrates an electronic device.

FIG. 6 illustrates a lighting device.

FIG. 7 illustrates lighting devices.

FIG. 8 illustrates car-mounted display devices and lighting devices.

FIGS. 9A and 9B illustrate a lighting device.

FIG. 10 is a graph showing current density-luminance characteristics of Light-emitting Elements 1 to 4.

FIG. 11 is a graph showing voltage-luminance characteristics of Light-emitting Elements 1 to 4.

FIG. 12 is a graph showing luminance-current efficiency characteristics of Light-emitting Elements 1 to 4.

FIG. 13 is a graph showing voltage-current characteristics of Light-emitting Elements 1 to 4.

FIG. 14 is a graph showing luminance-power efficiency characteristics of Light-emitting Elements 1 to 4.

FIG. 15 is a graph showing luminance-external quantum efficiency characteristics of Light-emitting Elements 1 to 4.

FIG. 16 shows emission spectra of Light-emitting Elements 1 to 4.

FIGS. 17A and 17B illustrate distributions of the HOMO and the LUMO of mCP.

FIGS. 18A and 18B illustrate distributions of the HOMO and the LUMO of mTPmCP.

FIG. 19 is a graph showing current density-luminance characteristics of Light-emitting Elements 5 to 8.

FIG. 20 is a graph showing voltage-luminance characteristics of Light-emitting Elements 5 to 8.

FIG. 21 is a graph showing luminance-current efficiency characteristics of Light-emitting Elements 5 to 8.

FIG. 22 is a graph showing voltage-current characteristics of Light-emitting Elements 5 to 8.

FIG. 23 is a graph showing luminance-power efficiency characteristics of Light-emitting Elements 5 to 8.

FIG. 24 is a graph showing luminance-external quantum efficiency characteristics of Light-emitting Elements 5 to 8.

FIG. 25 shows emission spectra of Light-emitting Elements 5 to 8.

### DETAILED DESCRIPTION OF THE INVENTION

Embodiments of the present invention will be described below with reference to the drawings. Note that the embodiments can be implemented in various different ways. It will be readily appreciated by those skilled in the art that modes and details of the embodiments can be modified in various ways without departing from the spirit and scope of the present invention. The present invention therefore should not be construed as being limited to the description of the embodiments.

Note that for easy understanding, the magnification ratio and the reduction ratio of each component in drawings is not constant, and thus the relation of thickness, length, and size of each component in the drawings does not necessarily show the ratios of thickness, length, and size of a light-emitting device which is an embodiment of the present invention. As for the reference numerals, the same numbers with different alphabets are considered as being in the same group in some cases. In the case where only the number is shown, the number indicates the group of the components with the same numbers with different alphabets.

### Embodiment 1

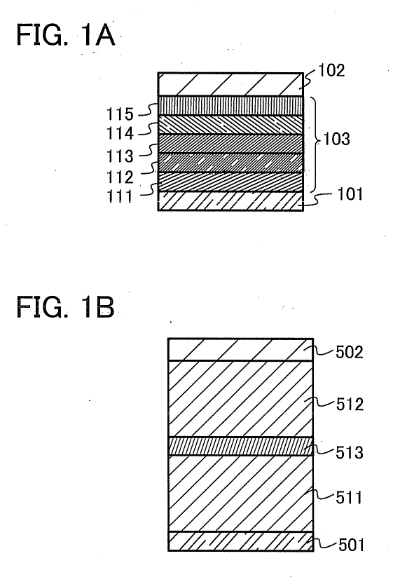

FIGS. 1A and 1B are each a schematic cross-sectional view of a light-emitting element of one embodiment of the present invention. The light-emitting element described in this embodiment includes an EL layer 103 provided between a pair of electrodes (first electrode 101 and second electrode 102) which are an electrode functioning as an anode (hereinafter referred to as anode) and an electrode functioning as a cathode (hereinafter referred to as cathode). The EL layer 103 includes a plurality of layers having different functions and the light-emitting element of this embodiment includes at least a light-emitting layer 113 exhibiting light by current flow and a hole-transport layer 112 provided in contact with the anode side of the light-emitting layer.

The hole-transport layer 112 includes a hole-transport material which is a first carbazole derivative having a carbazole skeleton. Note that both the HOMO and the LUMO of the first carbazole derivative are distributed over the carbazole skeleton. An N-phenyl carbazole derivative can be favorably used as such a carbazole derivative.

The light-emitting layer 113 contains an emission center substance for achieving desired light emission and a host material in which the emission center substance is dispersed. The host material includes a second carbazole derivative having a carbazole skeleton. The second carbazole derivative also has a skeleton other than the carbazole skeleton and the HOMO of the second carbazole derivative is distributed over the carbazole skeleton and the LUMO of the second carbazole derivative is not distributed over the carbazole skeleton but is distributed over the skeleton other than the carbazole skeleton.

In the light-emitting element of this embodiment which has the above-described structure, since both the HOMO of the hole-transport material of the hole-transport layer 112 and that of the host material of the light-emitting layer 113 are distributed over the carbazole skeletons, holes are injected to their carbazole skeleton. Because the HOMO level is substantially determined by the carbazole skeleton, the HOMO level of the light-emitting layer 113 and that of the hole-transport layer 112 can be close to each other. Thus, holes are injected smoothly from the hole-transport layer 112 to the light-emitting layer 113, which facilitates fabrication of a light-emitting element with low driving voltage.

At the same time, in the light-emitting element of this embodiment, the LUMO of the hole-transport material of the hole-transport layer 112 is distributed over the carbazole skeleton, and the LUMO of the host material of the light-emitting layer 113 is distributed over the skeleton other than the carbazole skeleton. Therefore, the skeletons to which electrons are injected are different therebetween. Since electrons are not readily injected to a carbazole skeleton, the LUMO level of the hole-transport material is shallower (has a smaller absolute value) than the LUMO level of the host material. Accordingly, penetration of electrons through the light-emitting layer 113 to the hole-transport layer 112 can be prevented and the probability of recombination can be increased; thus, a light-emitting element with high emission efficiency can be obtained.

Since a carbazole skeleton has an extremely wide band gap, the first carbazole derivative has a wide band gap and a high T₁ level. In addition, since the HOMO level of the carbazole skeleton is deep (has a large absolute value), the second carbazole derivative has a relatively wide band gap. Therefore, the structure of the light-emitting element of this embodiment can be favorably applied to a light-emitting element utilizing blue fluorescence or green to blue phosphorescence.

The skeleton other than the carbazole skeleton in the second carbazole derivative preferably includes a skeleton having an electron-transport property. The reason for this is that when the skeleton having an electron-transport property is included, electrons readily flow in the light-emitting layer 113 and driving voltage can be reduced. Moreover, light-emitting regions can be prevented from concentrating on the electron-transport layer side of the light-emitting layer 113 and concentration quenching or T-T annihilation can be suppressed, whereby a reduction in emission efficiency can be small. Even when the skeleton leads an increase in electron-transport property, electrons can be prevented from reaching the hole-transport layer 112 owing to the fact that the LUMO of the hole-transport material is shallower than the LUMO of the host material, so that a reduction in emission efficiency can be suppressed. Note that in that case, the LUMO of the second carbazole derivative may be distributed over the skeleton having an electron-transport property; alternatively, when another skeleton is included in the skeleton other than the carbazole skeleton, the LUMO may be distributed over the skeleton.

As a skeleton having an electron-transport property, an aromatic hydrocarbon group, a π-electron deficient heteroaromatic group, and the like can be given. Between them, an aromatic hydrocarbon group is preferred.

As an aromatic hydrocarbon group, a naphthyl group, a biphenyl group, a terphenyl group, a fluorenyl group, a triphenylenyl group or the like is preferably used, since a band gap of the second carbazole derivative can be kept wider and a triplet energy level thereof can be kept higher.

As a heteroaromatic group, a pyrazolyl group, an imidazolyl group, a triazolyl group, an oxadiazolyl group, a benzimidazolyl group, a benzoxazolyl group, a pyridinyl group, a pyrazinyl group, a pyrimidinyl group, a phenanthrolinyl group, or the like is preferably used, since a band gap of the second carbazole derivative can be kept wider and a triplet energy level thereof can be kept higher.

Specific examples of a carbazole derivative which can be favorably used as the first carbazole derivative are represented by Structural Formulae (100) to (107). Note that carbazole derivatives applicable to the first carbazole derivative are not limited to them.

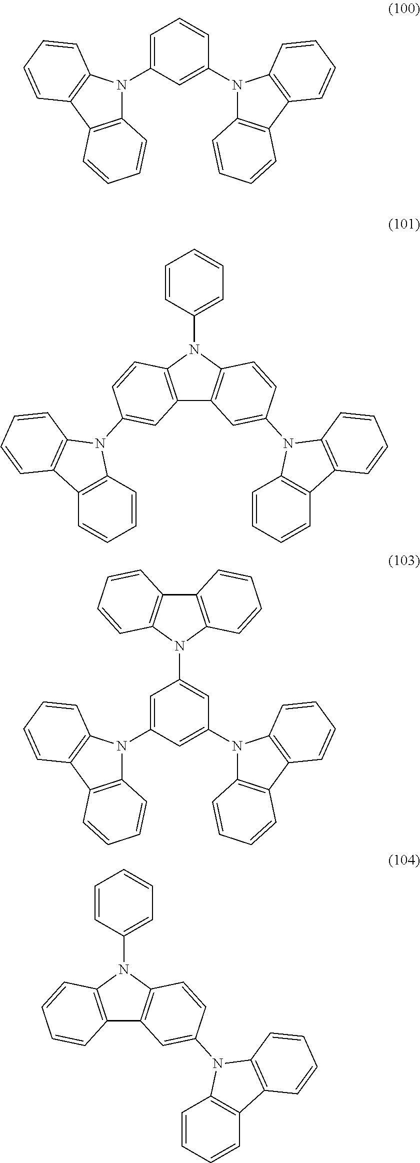

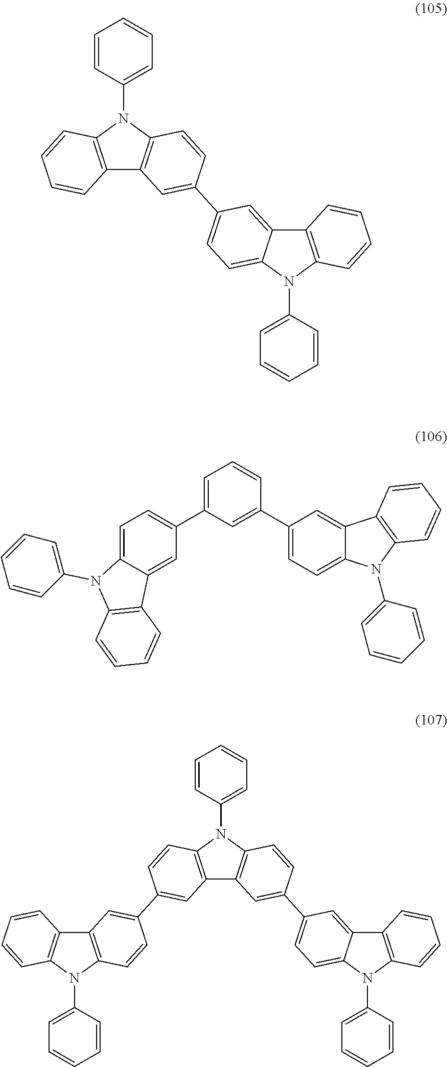 [SMILES: c1ccc(-n2c3ccccc3c3cc(-c4ccc5c(c4)c4ccccc4n5-c4ccccc4)ccc32)cc1 ; c1ccc(-n2c3ccccc3c3cc(-c4cccc(-c5ccc6c(c5)c5ccccc5n6-c5ccccc5)c4)ccc32)cc1 ; c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1]

Specific examples of a carbazole derivative which can be favorably used as the second carbazole derivative are represented by Structural Formulae (200) to (220). Note that carbazole derivatives applicable to the second carbazole derivative are not limited to them.

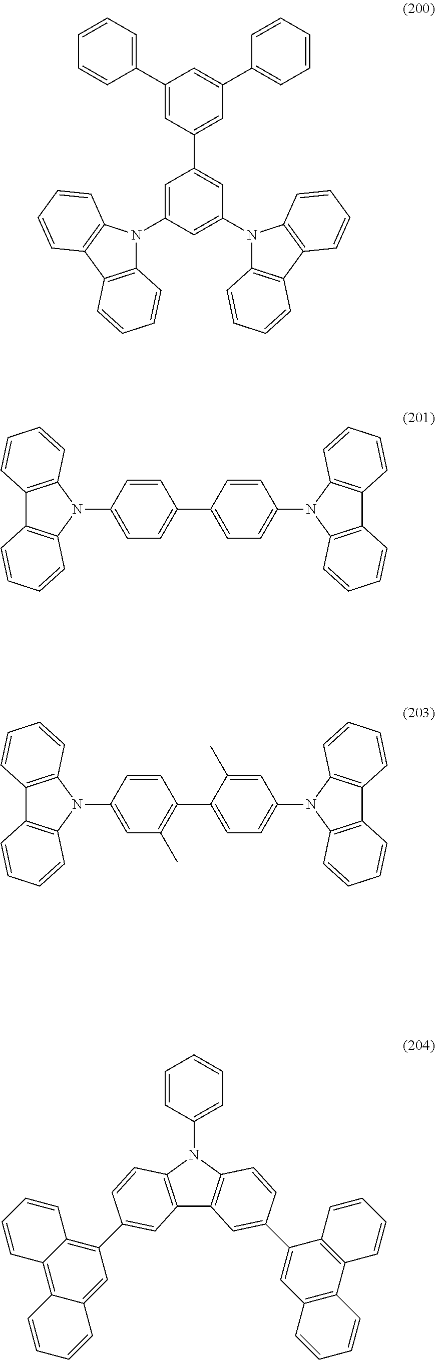 [SMILES: c1ccc(-c2cc(-c3ccccc3)cc(-c3cc(-n4c5ccccc5c5ccccc54)cc(-n4c5ccccc5c5ccccc54)c3)c2)cc1 ; c1ccc2c(c1)c1ccccc1n2-c1ccc(-c2ccc(-n3c4ccccc4c4ccccc43)cc2)cc1 ; Cc1cc(-n2c3ccccc3c3ccccc32)ccc1-c1ccc(-n2c3ccccc3c3ccccc32)cc1C ; c1ccc(-n2c3ccc(-c4cc5ccccc5c5ccccc45)cc3c3cc(-c4cc5ccccc5c5ccccc45)ccc32)cc1]

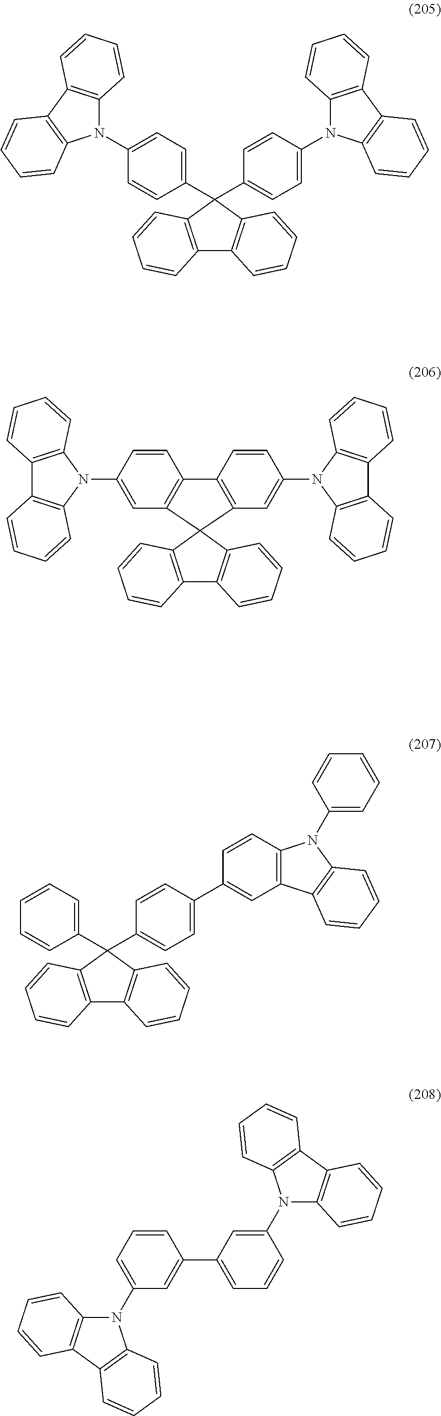 [SMILES: c1ccc2c(c1)-c1ccccc1C2(c1ccc(-n2c3ccccc3c3ccccc32)cc1)c1ccc(-n2c3ccccc3c3ccccc32)cc1 ; c1ccc2c(c1)-c1ccccc1C21c2cc(-n3c4ccccc4c4ccccc43)ccc2-c2ccc(-n3c4ccccc4c4ccccc43)cc21 ; c1ccc(-n2c3ccccc3c3cc(-c4ccc(C5(c6ccccc6)c6ccccc6-c6ccccc65)cc4)ccc32)cc1 ; c1cc(-c2cccc(-n3c4ccccc4c4ccccc43)c2)cc(-n2c3ccccc3c3ccccc32)c1]

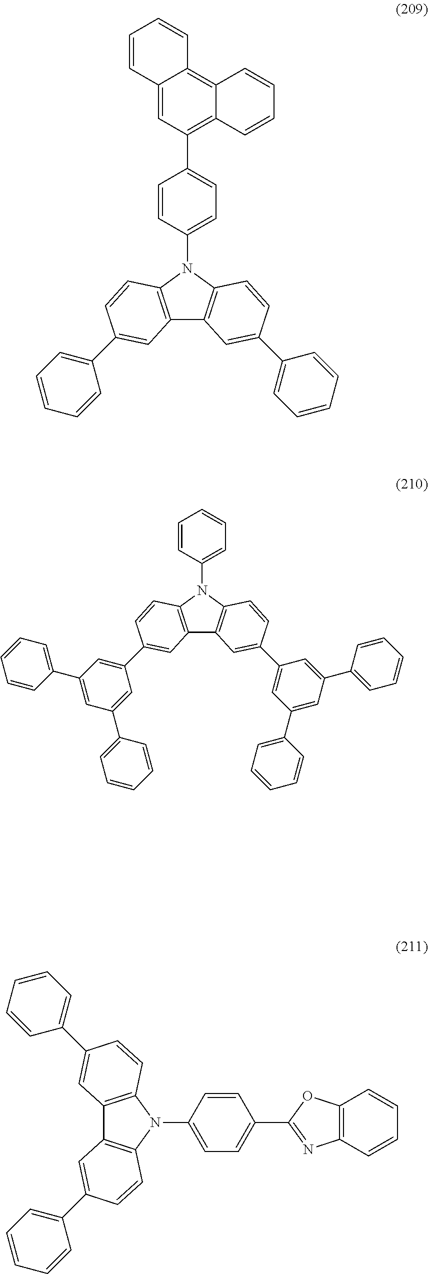 [SMILES: c1ccc(-c2ccc3c(c2)c2cc(-c4ccccc4)ccc2n3-c2ccc(-c3cc4ccccc4c4ccccc34)cc2)cc1 ; c1ccc(-c2cc(-c3ccccc3)cc(-c3ccc4c(c3)c3cc(-c5cc(-c6ccccc6)cc(-c6ccccc6)c5)ccc3n4-c3ccccc3)c2)cc1 ; c1ccc(-c2ccc3c(c2)c2cc(-c4ccccc4)ccc2n3-c2ccc(-c3nc4ccccc4o3)cc2)cc1]

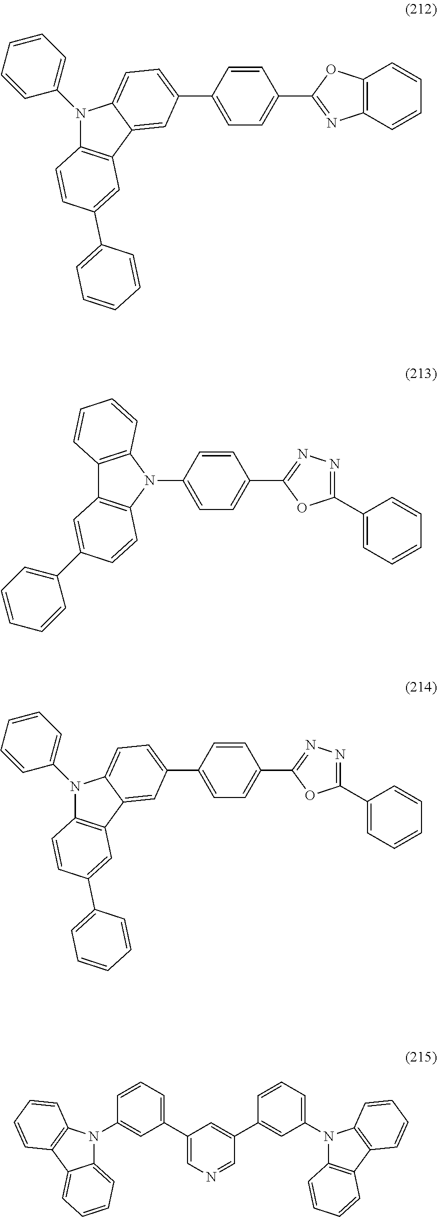 [SMILES: c1ccc(-c2ccc3c(c2)c2cc(-c4ccc(-c5nc6ccccc6o5)cc4)ccc2n3-c2ccccc2)cc1 ; c1ccc(-c2ccc3c(c2)c2ccccc2n3-c2ccc(-c3nnc(-c4ccccc4)o3)cc2)cc1 ; c1ccc(-c2ccc3c(c2)c2cc(-c4ccc(-c5nnc(-c6ccccc6)o5)cc4)ccc2n3-c2ccccc2)cc1 ; c1cc(-c2cncc(-c3cccc(-n4c5ccccc5c5ccccc54)c3)c2)cc(-n2c3ccccc3c3ccccc32)c1]

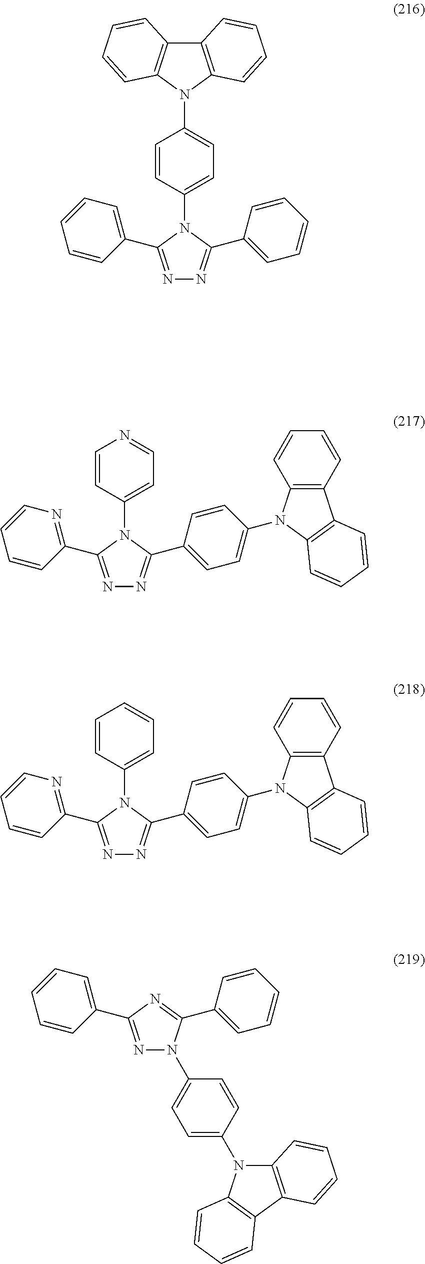 [SMILES: c1ccc(-c2nnc(-c3ccccc3)n2-c2ccc(-n3c4ccccc4c4ccccc43)cc2)cc1 ; c1ccc(-c2nnc(-c3ccc(-n4c5ccccc5c5ccccc54)cc3)n2-c2ccncc2)nc1 ; c1ccc(-n2c(-c3ccc(-n4c5ccccc5c5ccccc54)cc3)nnc2-c2ccccn2)cc1 ; c1ccc(-c2nc(-c3ccccc3)n(-c3ccc(-n4c5ccccc5c5ccccc54)cc3)n2)cc1]

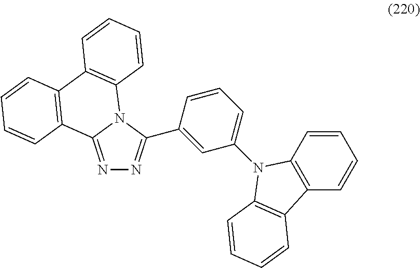 [SMILES: c1cc(-c2nnc3c4ccccc4c4ccccc4n23)cc(-n2c3ccccc3c3ccccc32)c1]

The structure of the light-emitting element will now be described.

The first electrode 101 and the second electrode 102 in FIG. 1A are an anode and a cathode, respectively. At least either of these electrodes is formed using a material having a light-transmitting property. The EL layer 103 is provided between these electrodes and the light-emitting layer 113 provided in the EL layer 103 can emit light by application of voltage between these electrodes to supply current to the EL layer 103. As described above, the EL layer 103 includes at least the light-emitting layer 113 in which the emission center substance is dispersed in the host material, and the hole-transport layer 112 formed in contact with the anode side of the light-emitting layer 113.

For the anode, it is preferable to use metals, alloys, conductive compounds, mixtures thereof, or the like which have a high work function (specifically, a work function of 4.0 eV or more). As specific examples, indium oxide-tin oxide (ITO: indium tin oxide), indium oxide-tin oxide containing silicon or silicon oxide, indium oxide-zinc oxide (indium zinc oxide), indium oxide containing tungsten oxide and zinc oxide, and the like are given. Films of these conductive metal oxides are usually formed by sputtering, but may be formed by application of a sol-gel method or the like. For example, indium oxide-zinc oxide can be formed by a sputtering method using indium oxide into which 1 wt % to 20 wt % of zinc oxide is added, as a target. Indium oxide containing tungsten oxide and zinc oxide can be formed by a sputtering method using a target in which 0.5 wt % to 5 wt % of tungsten oxide and 0.1 wt % to 1 wt % of zinc oxide with respect to indium oxide are included. Besides, gold (Au), platinum (Pt), nickel (Ni), tungsten (W), chromium (Cr), molybdenum (Mo), iron (Fe), cobalt (Co), copper (Cu), palladium (Pd), nitrides of the metal materials (such as titanium nitride), and the like are given. Graphene can also be used.

For the cathode, it is possible to use metals, alloys, conductive compounds, mixtures thereof, or the like which have a low work function (specifically, a work function of 3.8 eV or less). Specific examples of such a cathode material include an element that belongs to Group 1 or 2 of the periodic table such as lithium (Li), cesium (Cs), magnesium (Mg), calcium (Ca), or strontium (Sr), an alloy containing any of these metals (e.g., MgAg or AlLi), a rare earth metal such as europium (Eu) or ytterbium (Yb), an alloy containing such a rare earth metal. However, when an electron-injection layer 115 is provided between the cathode and an electron-transport layer 114, for the cathode, any of a variety of conductive materials such as Al, Ag, ITO, or indium oxide-tin oxide containing silicon or silicon oxide can be used regardless of the work function. Films of these electrically conductive materials can be formed by a sputtering method, an inkjet method, a spin coating method, or the like.

The stacked-layer structure of the EL layer 103 is not particularly limited as long as the above-described structure is employed; the stacked-layer structure can be formed by appropriately combining a carrier-transport layer containing a substance with a high carrier-transport property, a carrier-injection layer containing a substance with a high carrier-injection property, and a layer containing a bipolar substance (substance with high electron- and hole-transport properties), and the like. For example, as illustrated in FIG. 1A, a hole-injection layer 111, the electron-transport layer 114, the electron-injection layer 115, and the like can be combined, as appropriate, with the hole-transport layer 112 and the light-emitting layer 113. Needless to say, the EL layer may further include a layer having another function or may include a layer having a plurality of functions. In this embodiment, the EL layer 103 is described in which the hole-injection layer 111, the hole-transport layer 112, the light-emitting layer 113, the electron-transport layer 114, and the electron-injection layer 115 are stacked in this order over the first electrode 101. Specific materials to form each of the layers will be given below.

The hole-injection layer 111 is a layer which is provided in contact with the anode and contains a substance having a high hole-injection property. The hole-injection layer 111 can be formed using molybdenum oxide, vanadium oxide, ruthenium oxide, tungsten oxide, manganese oxide, or the like. Alternatively, the hole-injection layer 111 can be formed using a phthalocyanine-based compound such as phthalocyanine (abbreviation: H₂Pc) or copper phthalocyanine (abbreviation: CuPc); an aromatic amine compound such as 4,4′-bis[N-(4-diphenylaminophenyl)-N-phenylamino]biphenyl (abbreviation: DPAB) or N,N′-bis{4-[bis(3-methylphenyl)amino]phenyl}-N,N′-diphenyl-(1,1′-biphenyl)-4,4′-diamine (abbreviation: DNTPD); a polymer such as poly(ethylenedioxythiophene)/poly(styrenesulfonic acid) (PEDOT/PSS); or the like.

Alternatively, the hole-injection layer 111 can be formed using a composite material in which a substance exhibiting an acceptor property with respect to a substance having a high hole-transport property is contained in the substance having a high hole-transport property. Note that when a layer of the composite material is formed in contact with the anode, a material for forming the anode can be selected regardless of its work function. In other words, besides a material with a high work function, a material with a low work function may also be used for the anode. As the substance exhibiting an acceptor property, 7,7,8,8-tetracyano-2,3,5,6-tetrafluoroquinodimethane (abbreviation: F₄-TCNQ), chloranil, and the like are given. In addition, a transition metal oxide is given. For example, oxides of metals that belong to Group 4 to Group 8 of the periodic table can be used. Specifically, vanadium oxide, niobium oxide, tantalum oxide, chromium oxide, molybdenum oxide, tungsten oxide, manganese oxide, and rhenium oxide are preferable because their electron-accepting property is high. Among these metal oxides, molybdenum oxide is especially preferable because it is stable in the air, has a low hygroscopic property, and is easily handled.

As the substance having a high hole-transport property used for the composite material, any of a variety of compounds such as an aromatic amine compound, a carbazole derivative, an aromatic hydrocarbon, and a polymer (including an oligomer and a dendrimer) can be used. Specifically, a substance having a hole mobility of 10⁻⁶ cm²/Vs or higher is preferably used. Note that any other substances may also be used as long as the hole-transport property thereof is higher than the electron-transport property thereof. The organic compounds that can be used for the composite material are specifically given below.

As the aromatic amine compounds, for example, there are N,N′-di(p-tolyl)-N,N′-diphenyl-p-phenylenediamine (abbreviation: DTDPPA), DPAB, DNTPD, and 1,3,5-tris[N-(4-diphenylaminophenyl)-N-phenylamino]benzene (abbreviation: DPA3B).

As the carbazole derivatives which can be used for the composite material, the followings are given specifically: 3-[N-(9-phenylcarbazol-3-yl)-N-phenylamino]-9-phenylcarbazole (abbreviation: PCzPCA1); 3,6-bis[N-(9-phenylcarbazol-3-yl)-N-phenylamino]-9-phenylcarbazole (abbreviation: PCzPCA2); 3-[N-(1-naphthyl)-N-(9-phenylcarbazol-3-yl)amino]-9-phenylcarbazole (abbreviation: PCzPCN1); and the like.

Other examples of the carbazole derivatives which can be used for the composite material include 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthryl)phenyl]-9H-carbazole (abbreviation: CzPA), and 1,4-bis[4-(N-carbazolyl)phenyl]-2,3,5,6-tetraphenylbenzene.

Examples of the aromatic hydrocarbon which can be used for the composite material include 2-tert-butyl-9,10-di(2-naphthyl)anthracene (abbreviation: t-BuDNA); 2-tert-butyl-9,10-di(1-naphthyl)anthracene; 9,10-bis(3,5-diphenylphenyl)anthracene (abbreviation: DPPA); 2-tert-butyl-9,10-bis(4-phenylphenyl)anthracene (abbreviation: t-BuDBA); 9,10-di(2-naphthyl)anthracene (abbreviation: DNA); 9,10-diphenylanthracene (abbreviation: DPAnth); 2-tert-butylanthracene (abbreviation: t-BuAnth); 9,10-bis(4-methyl-1-naphthyl)anthracene (abbreviation: DMNA); 2-tert-butyl-9,10-b is [2-(1-naphthyl)phenyl]anthracene; 9,10-bis[2-(1-naphthyl)phenyl]anthracene; 2,3,6,7-tetramethyl-9,10-di(1-naphthyl)anthracene; 2,3,6,7-tetramethyl-9,10-di(2-naphthyl)anthracene; 9,9′-bianthryl; 10,10′-diphenyl-9,9′-bianthryl; 10,10′-bis(2-phenylphenyl)-9,9′-bianthryl; 10,10′-bis[(2,3,4,5,6-pentaphenyl)phenyl]-9,9′-bianthryl; anthracene; tetracene; rubrene; perylene, and 2,5,8,11-tetra(tert-butyl)perylene. Besides those materials, pentacene, coronene, or the like can be used. The aromatic hydrocarbon which has a hole mobility of 1×10⁻⁶ cm²/Vs or higher and which has 14 to 42 carbon atoms is particularly preferable.

The aromatic hydrocarbon which can be used for the composite material may have a vinyl skeleton. As the aromatic hydrocarbon having a vinyl group, 4,4′-bis(2,2-diphenylvinyl)biphenyl (abbreviation: DPVBi) and 9,10-bis[4-(2,2-diphenylvinyl)phenyl]anthracene (abbreviation: DPVPA) are given, for example.

Moreover, a polymer such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), or poly[N,N′-bis(4-butylphenyl)-N,N′-bis(phenyl)benzidine (abbreviation: Poly-TPD) can also be used.

Note that a layer formed using such a composite material can be very suitably used for optical design that is performed to control the light extraction efficiency, directivity, or the like of light emitted from the light-emitting layer 113 because the driving voltage hardly varies even when the layer formed using the composite material is formed to be thick or thin.

The hole-transport layer 112 includes a hole-transport material which is the first carbazole derivative having a carbazole skeleton. Note that both the HOMO and the LUMO of the first carbazole derivative are distributed over the carbazole skeleton.

As the first carbazole derivative, any of the substances represented by Structural Formulae (100) to (107) can be used.

The light-emitting layer 113 is a layer containing an emission substance. The light-emitting layer 113 is what is called a host-guest type light-emitting layer in which an emission center substance is dispersed in a host material as described above.

There is no particular limitation on the emission center substance that is used, and a known fluorescent material or a known phosphorescent material can be used. As a fluorescent material, for example, in addition to N,N′-bis[4-(9H-carbazol-9-yl)phenyl]-N,N′-diphenylstilbene-4,4′-diamine (abbreviation: YGA2S), and 4-(9H-carbazol-9-yl)-4′-(10-phenyl-9-anthryl)triphenylamine (abbreviation: YGAPA), there are fluorescent materials with an emission wavelength of 450 nm or more, such as 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: BP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis[N,N′,N′-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), NN,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis {2-[4-(dimethylamino)phenyl]ethenyl}-4H-pyran-4-ylidene)propanedinitrile (abbreviation: BisDCM), and 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM). As phosphorescent materials, for example, in addition to bis[2-(4′,6′-difluorophenyl)pyridinato-N,C^{2′}]iridium(III)tetrakis(1-pyrazolyl)borate (abbreviation: FIr6), there are phosphorescent materials with an emission wavelength in the range of 470 nm to 500 nm, such as bis[2-(4′,6′-difluorophenyl)pyridinato-N,C^{2′}]iridium(III)picolinate (abbreviation: FIrpic), bis[2-(3′,5′-bistrifluoromethylphenyl)pyridinato-N, C^{2′}]iridium(III)picolinate (abbreviation: Ir(CF₃ppy)₂(pic)), and bis[2-(4′,6′-difluorophenyl)pyridinato-N,C^{2′}]iridium(III)acetylacetonate (abbreviation: FIracac); phosphorescent materials with an emission wavelength of 500 nm or more (materials which emit green light), such as tris(2-phenylpyridinato)iridium(III) (abbreviation: Ir(ppy)₃), bis(2-phenylpyridinato)iridium(III)acetylacetonate (abbreviation: Ir(ppy)₂(acac)), tris(acetylacetonato)(monophenanthroline)terbium(III) (abbreviation: Tb(acac)₃(Phen)), bis(benzo[h]quinolinato)iridium(III)acetylacetonate) (abbreviation: Ir(bzq)₂(acac)), bis(2,4-diphenyl-1,3-oxazolato-N, C^{2′})iridium(III)acetylacetonate (abbreviation: Ir(dpo)₂(acac)), bis[2-(4′-perfluorophenylphenyl)pyridinato]iridium(III)acetylacetonate (abbreviation: Ir(p-PF-ph)₂(acac)), bis(2-phenylbenzothiazolato-N,C^{2′})iridium(III)acetylacetonate (abbreviation: Ir(bt)₂(acac)), bis[2-(2′-benzo[4,5-a]thienyl)pyridinato-N, C^{3′}]iridium(III)acetylacetonate (abbreviation: Ir(btp)₂(acac)), bis(1-phenylisoquinolinato-N, C^{2′})iridium(III)acetylacetonate (abbreviation: Ir(piq)₂(acac)), (acetylacetonato)bis[2,3-bis(4-fluorophenyl)quinoxalinato]iridium(III) (abbreviation: Ir(Fdpq)₂(acac)), (acetylacetonato)bis(2,3,5-triphenylpyrazinato)iridium(III) (abbreviation: Ir(tppr)₂(acac)), (2,3,7,8,12,13,17,18-octaethyl-21H,23H-porphine)platinum(II) (abbreviation: PtOEP), tris(1,3-diphenyl-1,3-propanedionato)(monophenanthroline)europium(III) (abbreviation: Eu(DBM)₃(Phen)), and tris[1-(2-thenoyl)-3,3,3-trifluoroacetonato](monophenanthroline)europium(III) (abbreviation: Eu(TTA)₃(Phen)); and the like. Any of the above materials and other known materials may be selected in consideration of the emission color of each EL element.

The host material includes the second carbazole derivative having a carbazole skeleton. The second carbazole derivative also has a skeleton (second skeleton) other than the carbazole skeleton and the HOMO of the second carbazole derivative is distributed over the carbazole skeleton and the LUMO of the second carbazole derivative is distributed over the skeleton other than the carbazole skeleton.

As the second carbazole derivative, any of the carbazole derivatives represented by Structural Formulae (200) to (220) above can be used. As described below, the HOMO of mTPmCP which is the carbazole derivative represented by Structural Formula (200) is distributed over the carbazole skeleton. Moreover, mPmCP has a m-terphenyl skeleton as the second skeleton and the LUMO of mTPmCP is distributed over the m-terphenyl skeleton.

The electron-transport layer 114 is a layer which contains a substance having a high electron-transport property. For example, a layer containing a metal complex having a quinoline skeleton or a benzoquinoline skeleton, such as tris(8-quinolinolato)aluminum (abbreviation: Alq), tris(4-methyl-8-quinolinolato)aluminum (abbreviation: Almq₃), bis(10-hydroxybenzo[h]quinolinato)beryllium (abbreviation: BeBq₂), or bis(2-methyl-8-quinolinolato)(4-phenylphenolato)aluminum (abbreviation: BAlq) is used. Alternatively, a metal complex having an oxazole-based or thiazole-based ligand, such as bis[2-(2-hydroxyphenyl)benzoxazolato]zinc (abbreviation: Zn(BOX)₂) or bis[2-(2-hydroxyphenyl)benzothiazolato]zinc (abbreviation: Zn(BTZ)₂), or the like can be used. Besides the metal complexes, 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 3-(4-biphenylyl)-4-phenyl-5-(4-tert-butylphenyl)-1,2,4-triazole (abbreviation: TAZ), bathophenanthroline (abbreviation: BPhen), bathocuproine (abbreviation: BCP), or the like can also be used. The substances mentioned here are mainly ones that have an electron mobility of 10⁻⁶ cm²/Vs or higher. Note that another substance may be used for the electron-transport layer 114 as long as the substance has an electron-transport property higher than a hole-transport property.

The electron-transport layer 114 is not limited to a single layer and may be a stack of two or more layers containing the substances given above.

A layer for controlling transport of electron carriers may be provided between the electron-transport layer 114 and the light-emitting layer 113. This is a layer formed by addition of a small amount of a substance having a high electron-trapping property to the aforementioned material having a high electron-transport property, and capable of adjusting carrier balance by suppressing transport of electrons. Such a structure is very effective in suppressing problems (e.g., reduction in element lifetime) caused by a phenomenon in which an electron fails to undergo recombination and passes through the light-emitting layer 113.

For the electron-injection layer 115, an alkali metal, an alkaline earth metal, or a compound thereof, such as lithium, calcium, lithium fluoride (LiF), cesium fluoride (CsF), or calcium fluoride (CaF₂), can be used. Alternatively, a material in which a layer formed using a substance exhibiting an electron-transport property contains a substance exhibiting an electron-donating property (typically, an alkali metal, an alkaline earth metal, or a compound thereof) with respect to the substance exhibiting an electron-transport property (the material having a donor level), for example, a material in which Alq contains Mg can be used for the electron-injection layer 115. Note that the use of the material having a donor level for the electron-injection layer 115 is preferred because electron injection from the cathode is effectively performed.

Note that the EL layer 103 may have a structure in which a plurality of light-emitting units are stacked between the first electrode 501 and the second electrode 502 as illustrated in FIG. 1B. In that case, a charge-generation layer 513 is preferably provided between a first light-emitting unit 511 and a second light-emitting unit 512 which are stacked. The charge-generation layer 513 can be formed using the above-mentioned composite material. Further, the charge-generation layer 513 may have a stacked structure of a layer formed using the composite material and a layer formed using another material. In that case, as the layer formed using another material, a layer containing an electron donating substance and a substance having a high electron-transport property, a layer formed of a transparent conductive film, or the like can be used.

An EL element having such a structure does not easily invite problems such as energy transfer and quenching between the light-emitting units and has more choices of materials, thereby readily leading to both high emission efficiency and a long lifetime. It is also easy for such an EL element to exhibit phosphorescence from one of the light-emitting units and fluorescence from the other of the light-emitting units.

Although FIG. 1B illustrates a structure in which two light-emitting units (the first light-emitting unit 511 and the second light-emitting unit 512) are stacked, three or more light-emitting units can be stacked. In such a case, charge-generation layers are preferably provided between the light-emitting units.

The light-emitting unit has a structure similar to the structure of the EL layer 103 in FIG. 1A, and may be formed by combining functional layers described as components of the EL layer in FIG. 1A as appropriate, such as an electron-transport layer, an electron-injection layer, a hole-injection layer, and a bipolar layer, in addition to the light-emitting layer and the hole-transport layer. In the case of the light-emitting element in this embodiment, these functional layers other than the light-emitting layer and the hole-transport layer are not necessarily provided and another functional layer may be provided. The detailed explanation of these layers is given above and a repeated explanation thereof is omitted. Refer to the description of the EL layer 103 in FIG. 1A.

Any of various methods can be employed for forming the EL layer 103 regardless of whether it is a dry process or a wet process. For example, a vacuum evaporation method, an inkjet method, a spin coating method or the like may be used. Different formation methods may be used for the electrodes or the layers.

Similarly, the electrodes may be formed by a wet process such as a sol-gel process or by a wet process using a metal paste. Alternatively, the electrodes may be formed by a dry method such as a sputtering method or a vacuum evaporation method.

In the light-emitting element having the above-described structure, current flows due to a potential difference made between the first electrode 101 and the second electrode 102, a hole and an electron recombines in the light-emitting layer 113 which includes a substance having a high light-emitting property, and light is emitted. That is, a light-emitting region is formed in the light-emitting layer 113.

The emitted light is extracted out through one or both of the first electrode 101 and the second electrode 102. Therefore, one or both of the first electrode 101 and the second electrode 102 are light-transmitting electrodes. In the case where only the first electrode 101 is a light-transmitting electrode, light is extracted from the substrate side through the first electrode 101. Meanwhile, when only the second electrode 102 is a light-transmitting electrode, light is extracted from the side opposite to the substrate side through the second electrode 102. In the case where each of the first electrode 101 and the second electrode 102 is a light-transmitting electrode, light is extracted from both of the substrate side and the side opposite to the substrate through the first electrode 101 and the second electrode 102.

The structure of the layers provided between the first electrode 101 and the second electrode 102 is not limited to the aforementioned one. However, it is preferable that a light-emitting region where holes and electrons recombine be positioned away from the first electrode 101 and the second electrode 102 so as to prevent quenching due to the proximity of the light-emitting region and a metal used for electrodes and carrier-injection layers.

As for the electron-transport layer 114 in direct contact with the light-emitting layer, in order to suppress energy transfer from an exciton which is generated in the light-emitting layer 113, it is preferable that the energy gap thereof be wider than the energy gaps of the host material and the emission center substance. In the light-emitting element in this embodiment, the hole-transport material included in the hole-transport layer 112 inevitably has a wider energy gap than the host material; therefore, energy transfer from the light-emitting layer 113 to the hole-transport layer 112 is suppressed, which contributes to prevention of a reduction in emission efficiency.

### Embodiment 2

This embodiment shows a light-emitting device including a light-emitting element described in Embodiment 1.

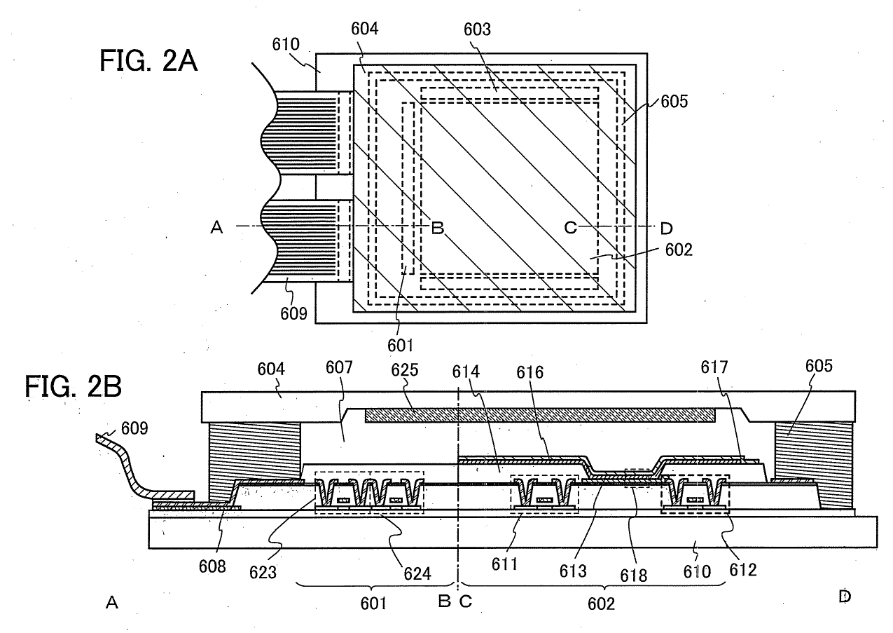

This embodiment shows an example of the light-emitting device fabricated using a light-emitting element described in Embodiment 1 with reference to FIGS. 2A and 2B. Note that FIG. 2A is a top view illustrating the light-emitting device and FIG. 2B is a cross-sectional view taken along lines A-B and C-D in FIG. 2A. The light-emitting device includes a driver circuit portion (source line driver circuit) 601, a pixel portion 602, and a driver circuit portion (gate line driver circuit) 603 which are illustrated with dotted lines. These portions control light emission of the light-emitting element. A reference numeral 604 denotes a sealing substrate; 605, a sealing material; and 607, a space surrounded by the sealing material 605.

A lead wiring 608 is a wiring for transmitting signals to be inputted into the source line driver circuit 601 and the gate line driver circuit 603 and receiving signals such as a video signal, a clock signal, a start signal, and a reset signal from an FPC (flexible printed circuit) 609 serving as an external input terminal. Although the FPC is illustrated alone here, a printed wiring board (PWB) may be attached to the FPC. The light-emitting device in this specification includes, in its category, not only the light-emitting device itself but also a module having the light-emitting device provided with the FPC or the PWB attached to the FPC.

Next, a cross-sectional structure is described with reference to FIG. 2B. The driver circuit portions (601, 603) and the pixel portion 602 are formed over an element substrate 610. In this embodiment, the source line driver circuit 601, which is the driver circuit portion, and one pixel of the pixel portion 602 are shown.

In the source line driver circuit 601, a CMOS circuit is formed in which an n-channel TFT 623 and a p-channel TFT 624 are combined. Such a driver circuit may be formed by using various circuits such as a CMOS circuit, a PMOS circuit, or an NMOS circuit. Although this embodiment illustrates a driver-integrated type where the driver circuit is formed over the substrate, the present invention is not limited to this structure, and the driver circuit may be formed outside the substrate, not over the substrate.

The pixel portion 602 is formed with a plurality of pixels including a switching TFT 611, a current controlling TFT 612, and a first electrode 613 electrically connected with a drain of the current controlling TFT 612. An insulator 614 is formed to cover the end portions of the first electrode 613. Here, the insulator 614 is formed using a positive photosensitive acrylic resin film.

In order to improve the coverage, the insulator 614 is formed to have a curved surface at its upper or lower end portion. For example, in the case of using positive photosensitive acrylic resin for the insulator 614, only the upper end portion of the insulator 614 preferably has a curved surface with a radius of curvature of 0.2 μm to 3 μm. As the insulator 614, it is possible to use either a negative photosensitive resin or a positive photosensitive resin.

A layer 616 including an organic compound and a second electrode 617 are formed over the first electrode 613. As a material used for the first electrode 613 which functions as an anode, a material having a high work function is preferably used. For example, it is possible to use a single-layer film of an ITO film, an indium tin oxide film including silicon, an indium oxide film including zinc oxide at 2 wt % to 20 wt %, a titanium nitride film, a chromium film, a tungsten film, a Zn film, a Pt film, or the like. Alternatively, it is possible to use a stack of a titanium nitride, film and a film including aluminum as its main component, a stack of three layers of a titanium nitride film, a film including aluminum as its main component, and a titanium nitride film, or the like. The stacked-layer structure achieves low wiring resistance, favorable ohmic contact, and a function as an anode.

The layer 616 including an organic compound is the EL layer explained in Embodiment 1 and is formed by any of a variety of methods such as an evaporation method using an evaporation mask, an inkjet method, and a spin coating method. Further, the layer 616 including an organic compound may include another material such as a low molecular-weight compound or a polymer (including an oligomer, and a dendrimer).

As a material used for the second electrode 617, which is formed over the layer 616 including an organic compound and serves as a cathode, a material having a low work function (e.g., Al, Mg, Li, Ca, or an alloy or a compound thereof, such as MgAg, MgIn, or AlLi) is preferably used. In the case where light generated in the layer 616 including an organic compound passes through the second electrode 617, the second electrode 617 is preferably formed using a stack of a thin metal film and a transparent conductive film (ITO, indium oxide containing zinc oxide at 2 wt % to 20 wt %, indium tin oxide containing silicon, zinc oxide (ZnO), or the like).

Note that a light-emitting element 618 includes the first electrode 613, the layer 616 including an organic compound, and the second electrode 617. The light-emitting element 618 has the structure described in Embodiment 1. The pixel portion, which includes a plurality of light-emitting elements, in the light-emitting device of this embodiment may include both the light-emitting element having the structure described in Embodiment 1 and the light-emitting element having a structure other than that structure.

The sealing substrate 604 is attached to the element substrate 610 with the sealing material 605, so that the light-emitting element 618 is provided in the space 607 surrounded by the element substrate 610, the sealing substrate 604, and the sealing material 605. The space 607 may be filled with filler, and may be filled with an inert gas (such as nitrogen or argon), the sealing material 605, or the like, for example. In this Embodiment, the space 607 is filled with an inert gas, and a desiccant 625 is further provided in the space.

An epoxy-based resin is preferably used for the sealing material 605. A material used for the sealing material 605 is desirably a material which does not transmit moisture or oxygen as much as possible. As a material for the sealing substrate 604, a plastic substrate made of FRP (fiberglass-reinforced plastics), PVF (poly(vinyl fluoride)), a polyester, an acrylic resin, or the like can be used besides a glass substrate or a quartz substrate.

In this manner, it is possible to obtain the light-emitting device fabricated using the light-emitting element described in Embodiment 1.

Since the light-emitting device in this embodiment is formed using the light-emitting element described in Embodiment 1, a light-emitting device having favorable characteristics can be provided. Specifically, since the light-emitting element described in Embodiment 1 has high emission efficiency, a light-emitting device with low power consumption can be provided. In addition, since a light-emitting element driven at low driving voltage can be obtained, a light-emitting device driven at low driving voltage can be provided. Further, since a light-emitting element with high reliability can be obtained, a light-emitting device with high reliability can be provided.

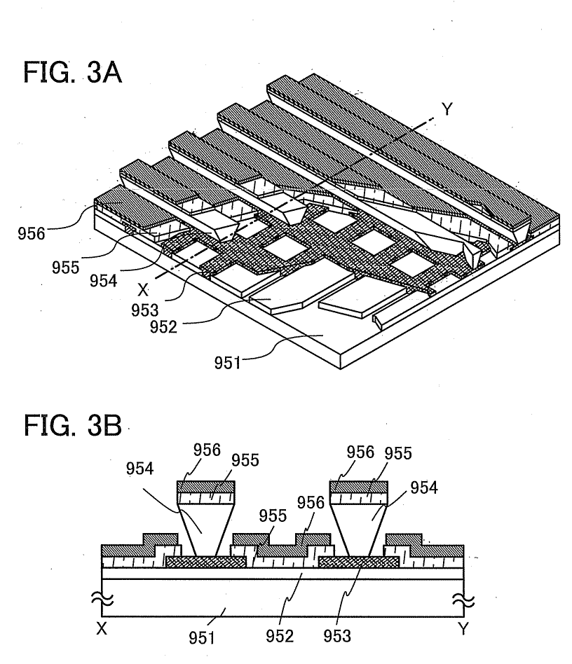

An active matrix light-emitting device is described above, whereas a passive matrix light-emitting device is described below. FIGS. 3A and 3B illustrate a passive matrix light-emitting device fabricated using one embodiment of the present invention. FIG. 3A is a perspective view of the light-emitting device, and FIG. 3B is a cross-sectional view taken along line X-Y in FIG. 3A. In FIGS. 3A and 3B, an electrode 952 and an electrode 956 are provided over a substrate 951, and a layer 955, which corresponds to the EL layer explained in Embodiment 1 and includes an organic compound, is provided between the electrodes 952 and 956. An end portion of the electrode 952 is covered with an insulating layer 953. A partition layer 954 is provided over the insulating layer 953. The side surfaces of the partition layer 954 are aslope such that the distance between both side surfaces is gradually narrowed toward the surface of the substrate. That is, a cross section in a short side of the partition layer 954 is a trapezoidal shape, and a lower side (a side which is in the same direction as a plane direction of the insulating layer 953 and in contact with the insulating layer 953) is shorter than an upper side (a side which is in the same direction as the plane direction of the insulating layer 953 and not in contact with the insulating layer 953). By providing the partition layer 954 in this manner, defects of the light-emitting element due to the crosstalk and the like can be prevented. The passive matrix light-emitting device can also be operated with low power consumption by including the light-emitting element described in Embodiment 1, which is driven at low driving voltage.

Since many minute light-emitting elements arranged in a matrix in the light-emitting device described above can each be controlled, the light-emitting device can be suitably used as a display device for displaying images.

### Embodiment 3

This embodiment shows electronic devices each including, as a part thereof, the light-emitting element described in Embodiment 1. The light-emitting element described in Embodiment 1 has high emission efficiency and reduced power consumption. The electronic devices described in this embodiment can thus have reduced power consumption.

Examples of the electronic devices to which the above light-emitting element is applied include television devices (also referred to as TV or television receivers), monitors for computers and the like, cameras such as digital cameras and digital video cameras, digital photo frames, cellular phones (also referred to as mobile phones or mobile phone devices), portable game machines, portable information terminals, audio playback devices, large game machines such as pachinko machines, and the like. Specific examples of these electronic devices are described below.

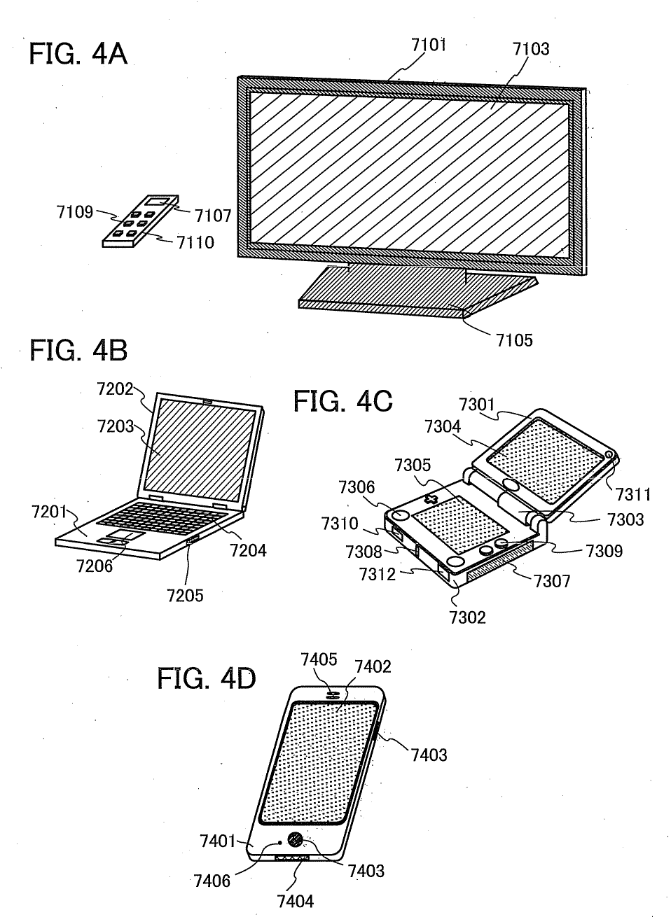

FIG. 4A illustrates an example of a television device. In the television device, a display portion 7103 is incorporated in a housing 7101. Here, the housing 7101 is supported by a stand 7105. Images can be displayed on the display portion 7103, and in the display portion 7103, the light-emitting elements described in Embodiment 1 are arranged in a matrix. Since the light-emitting elements have high emission efficiency and can be driven at low driving voltage, the television device having the display portion 7103 which includes the light-emitting elements consumes less power.

The television device can be operated with an operation switch of the housing 7101 or a separate remote controller 7110. With operation keys 7109 of the remote controller 7110, channels and volume can be controlled and images displayed on the display portion 7103 can be controlled. Furthermore, the remote controller 7110 may be provided with a display portion 7107 for displaying data output from the remote controller 7110.

Note that the television device is provided with a receiver, a modem, and the like. With the use of the receiver, general television broadcasting can be received. Moreover, when the television device is connected to a communication network with or without wires via the modem, one-way (from a sender to a receiver) or two-way (between a sender and a receiver or between receivers) information communication can be performed.

FIG. 4B illustrates a computer, which includes a main body 7201, a housing 7202, a display portion 7203, a keyboard 7204, an external connection port 7205, a pointing device 7206, and the like. Note that this computer is formed using the light-emitting elements described in Embodiment 1 and arranged in a matrix, for the display portion 7203. Since the light-emitting elements have high emission efficiency and can be driven at low driving voltage, this computer having the display portion 7203 which includes the light-emitting elements consumes less power.

FIG. 4C illustrates a portable game machine, which includes two housings, a housing 7301 and a housing 7302, connected to each other via a joint portion 7303 so that the portable game machine can be opened or closed. The housing 7301 incorporates a display portion 7304 including the light-emitting elements described in Embodiment 1 and arranged in a matrix, and the housing 7302 incorporates a display portion 7305. In addition, the portable game machine illustrated in FIG. 4C includes a speaker portion 7306, a recording medium insertion portion 7307, an LED lamp 7308, an input means (an operation key 7309, a connection terminal 7310, a sensor 7311 (a sensor having a function of measuring force, displacement, position, speed, acceleration, angular velocity, rotational frequency, distance, light, liquid, magnetism, temperature, chemical substance, sound, time, hardness, electric field, electric current, voltage, electric power, radiation, flow rate, humidity, gradient, oscillation, odor, or infrared rays), and a microphone 7312), and the like. Needless to say, the structure of the portable game machine is not limited to the above structure as long as a display portion including the light-emitting elements described in Embodiment 1 and arranged in a matrix is used as at least either the display portion 7304 or the display portion 7305, or both, and the structure can include other accessories as appropriate. The portable game machine illustrated in FIG. 4C has a function of reading out a program or data stored in a storage medium to display it on the display portion, and a function of sharing information with another portable game machine by wireless communication. Note that the portable game machine illustrated in FIG. 4C can have a variety of functions without limitation to the above-described functions. The portable game machine having the display portion 7304 can consume less power, since the light-emitting elements used in the display portion 7304 have high emission efficiency.

FIG. 4D illustrates an example of a cellular phone. The cellular phone is provided with a display portion 7402 incorporated in a housing 7401, operation buttons 7403, an external connection port 7404, a speaker 7405, a microphone 7406, and the like. Note that the cellular phone 7400 has the display portion 7402 including the light-emitting elements described in Embodiment 1 and are arranged in a matrix. Since the light-emitting elements have high emission efficiency and can be driven at low driving voltage, the cellular phone having the display portion 7402 which includes the light-emitting elements consumes less power.

When the display portion 7402 of the cellular phone illustrated in FIG. 4D is touched with a finger or the like, data can be input into the cellular phone. In this case, operations such as making a call and creating e-mail can be performed by touch on the display portion 7402 with a finger or the like.

There are mainly three screen modes of the display portion 7402. The first mode is a display mode mainly for displaying images. The second mode is an input mode mainly for inputting data such as text. The third mode is a display-and-input mode in which two modes of the display mode and the input mode are combined.

For example, in the case of making a call or creating e-mail, a text input mode mainly for inputting text is selected for the display portion 7402 so that text displayed on a screen can be inputted. In that case, it is preferable to display a keyboard or number buttons on almost all the area of the screen of the display portion 7402.

When a detection device which includes a sensor for detecting inclination, such as a gyroscope or an acceleration sensor, is provided inside the cellular phone, the direction of the cellular phone (whether the cellular phone is placed horizontally or vertically for a landscape mode or a portrait mode) is determined so that display on the screen of the display portion 7402 can be automatically switched.

The screen modes are switched by touching the display portion 7402 or operating the operation buttons 7403 of the housing 7401. Alternatively, the screen modes can be switched depending on the kinds of images displayed on the display portion 7402. For example, when a signal of an image displayed on the display portion is a signal of moving image data, the screen mode is switched to the display mode. When the signal is a signal of text data, the screen mode is switched to the input mode.

In the input mode, input by touching is detected by an optical sensor in the display portion 7402. When the input by touching is not performed for a certain period, the screen mode may be controlled so as to be switched from the input mode to the display mode.

The display portion 7402 may function as an image sensor. For example, an image of a palm print, a fingerprint, or the like is taken by touch on the display portion 7402 with the palm or the finger, whereby personal authentication can be performed. Further, by, providing a backlight or a sensing light source which emits near-infrared light in the display portion, an image of a finger vein, a palm vein, or the like can be taken.

Note that the structure described in this embodiment can be combined with any of the structures described in Embodiments 1 and 2 as appropriate.

As described above, the application range of the light-emitting device including the light-emitting elements described in Embodiment 1, is extremely wide; therefore, the light-emitting device can be applied to electronic devices of a variety of fields. By using the light-emitting element described in Embodiment 1, an electronic device with reduced power consumption can be provided.

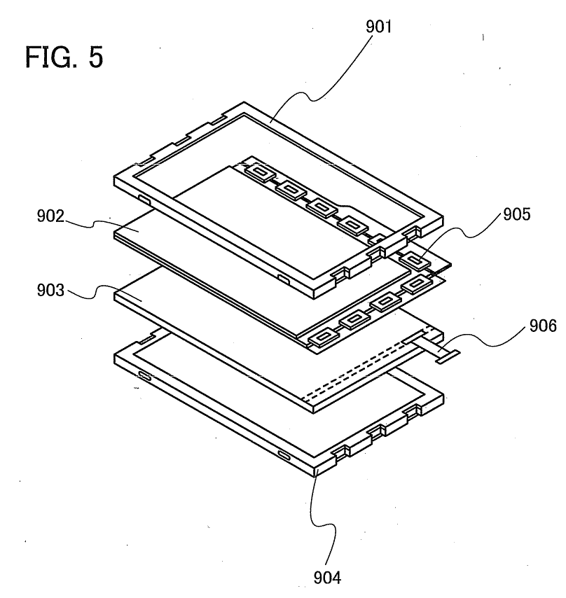

The light-emitting element described in Embodiment 1 can also be used for a lighting device. One mode of application of the light-emitting element described in Embodiment 1 to a lighting device is described with reference to FIG. 5. Note that the lighting device includes the light-emitting element described in Embodiment 1 as a light irradiation unit and at least includes an input-output terminal portion that supplies current to the light-emitting element. The light-emitting element is preferably shielded from the outside atmosphere (especially water) by sealing.

FIG. 5 illustrates an example of a liquid crystal display device using the light-emitting element described in Embodiment 1 for a backlight. The liquid crystal display device illustrated in FIG. 5 includes a housing 901, a liquid crystal layer 902, a backlight 903, and a housing 904. The liquid crystal layer 902 is connected to a driver IC 905. The light-emitting element described in Embodiment 1 is used in the backlight 903, to which current is supplied through a terminal 906.

The light-emitting element described in Embodiment 1 is used for the backlight of the liquid crystal display device, and thus a backlight with reduced power consumption can be obtained. By using the light-emitting element described in Embodiment 1, a planar lighting device can be fabricated, and the area can be increased. Thus, the area of the backlight can be increased, and the area of the liquid crystal display device can also be increased. Furthermore, the backlight formed using the light-emitting element described in Embodiment 1 can be thinner than a conventional one; accordingly, the display device can also be thinner.

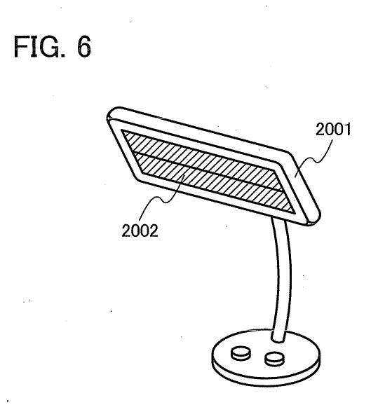

FIG. 6 illustrates an example in which the light-emitting element described in Embodiment 1 is used for a table lamp which is a lighting device. The table lamp illustrated in FIG. 6 includes a housing 2001 and a light source 2002, and the light-emitting element described in Embodiment 1 is used for the light source 2002.

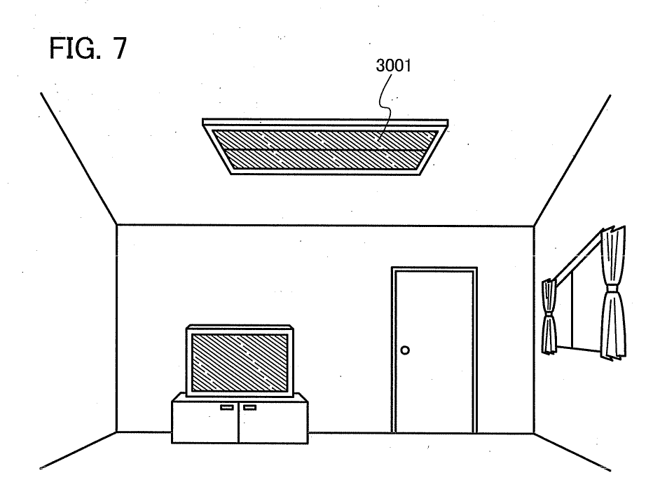

FIG. 7 illustrates an example in which the light-emitting element described in Embodiment 1 is used for indoor lighting device 3001. Since the light-emitting element described in Embodiment 1 has reduced power consumption, a lighting device with reduced power consumption can be provided. Further, since the light-emitting element described in Embodiment 1 can have a large area, the light-emitting element can be used for a large-area lighting device. Furthermore, since the light-emitting element described in Embodiment 1 is thin, a lighting device having a reduced thickness can be fabricated.

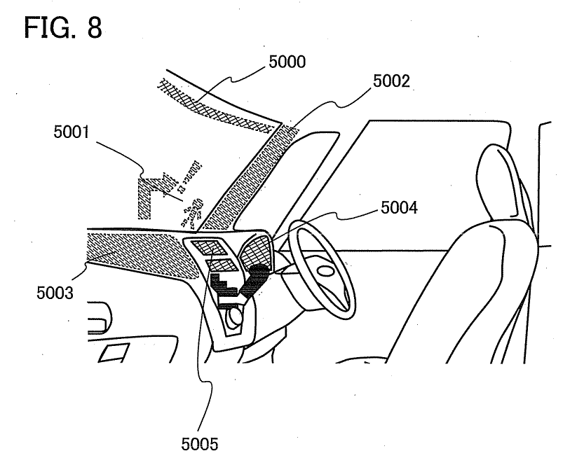

The light-emitting element described in Embodiment 1 can also be used for an automobile windshield or an automobile dashboard. FIG. 8 illustrates one mode in which the light-emitting element described in Embodiment 1 is used for an automobile windshield and an automobile dashboard. In regions 5000 to 5005, display is performed with the use of the light-emitting element described in Embodiment 1.

Light-emitting devices incorporating the light-emitting element described in Embodiment 1 are provided in the regions 5000 and 5001 in the automobile windshield. The light-emitting element described in Embodiment 1 can be formed into what is called a see-through light-emitting device, through which the opposite side can be seen, by including a first electrode and a second electrode formed with electrodes having a light-transmitting property. Such see-through light-emitting devices can be provided even in the automobile windshield without hindering the vision. Note that, when a transistor and the like for driving the light-emitting element is provided to the light-emitting device, it is preferable to use a transistor having a light-transmitting property, such as an organic transistor using an organic semiconductor material or a transistor using an oxide semiconductor.

A light-emitting device incorporating the light-emitting element described in Embodiment 1 is provided in the region 5002 in a pillar portion. An image taken by an imaging unit provided in the car body is shown in the region 5002, whereby the view hindered by the pillar portion can be compensated for. Similarly, the view hindered by the car body can be compensated for by showing an image taken by an imaging unit provided in the outside of the car body, in the region 5003 provided in the dashboard; thus, elimination of blind areas and enhancement of safety can be achieved. Showing an image so as to compensate for the area which a driver cannot see, makes it possible for the driver to confirm safety easily and comfortably.

A variety of kinds of information such as information of navigation, speedometer, tachometer, mileage, fuel meter, gearshift indicator, and air condition can be shown in the regions 5004 and 5005. The contents or layout of the display can be changed by a user as appropriate. Further, such information can be shown in the regions 5000 to 5003. Note that the regions 5000 to 5005 can also be used as lighting.

The light-emitting element described in Embodiment 1 has low driving voltage and consumes low power. Therefore, even when a large number of large screens are provided as in the regions 5000 to 5005, load on a battery can be reduced, which provides comfortable use. Thus, the light-emitting device using the light-emitting element described in Embodiment 1 can be suitably used as an in-vehicle light-emitting device.

### Embodiment 4

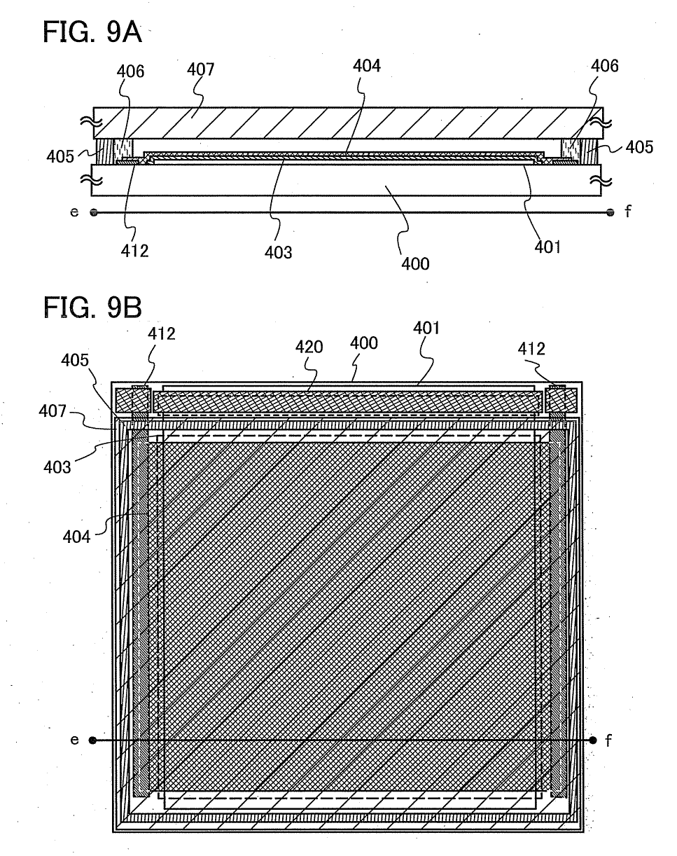

This embodiment shows an example in which the light-emitting element described in Embodiment 1 is used for a lighting device with reference to FIGS. 9A and 9B. FIG. 9B is a top view of the lighting device, and FIG. 9A is a cross-sectional view taken along line e-f in FIG. 9B.

In the lighting device in this embodiment, a first electrode 401 is formed over a substrate 400 which is a support and has a light-transmitting property. The first electrode 401 corresponds to the first electrode 101 in Embodiment 1. When light is extracted through the first electrode 401 side, the first electrode 401 is formed using a material having a light-transmitting property.

A pad 412 for applying voltage to a second electrode 404 is provided over the substrate 400.

An EL layer 403 is formed over the first electrode 401. The structure of the EL layer 403 corresponds to, for example, the structure of the EL layer 103 in Embodiment 1, or the structure in which the light-emitting units 511 and 512 and the charge-generation layer 513 are combined. For these structures, the description in Embodiment 1 can be referred to.

The second electrode 404 is formed to cover the EL layer 403. The second electrode 404 corresponds to the second electrode 102 in Embodiment 1. The second electrode 404 is formed using a material having high reflectance when light is extracted through the first electrode 401 side. The second electrode 404 is connected to the pad 412, whereby voltage is applied thereto.

As described above, the lighting device described in this embodiment includes a light-emitting element including the first electrode 401, the EL layer 403, and the second electrode 404. Since the light-emitting element has high emission efficiency, the lighting device in this embodiment has low power consumption.

The light-emitting element having the above structure is fixed to a sealing substrate 407 with sealing materials 405 and 406 to seal the light-emitting element, whereby the lighting device is completed. It is possible to use only either the sealing material 405 or the sealing material 406. In addition, the inner sealing material 406 (not shown in FIG. 9B) can be mixed with a desiccant, whereby moisture is adsorbed and the reliability is increased.

When parts of the pad 412 and the first electrode 401 are extended to the outside of the sealing materials 405 and 406, the extended parts can serve as external input terminals. An IC chip 420 provided with a converter or the like may be provided over the external input terminals.

In the above manner, the lighting device described in this embodiment includes the light-emitting element described in Embodiment 1, and thus can be a lighting device with low power consumption.

### Example 1

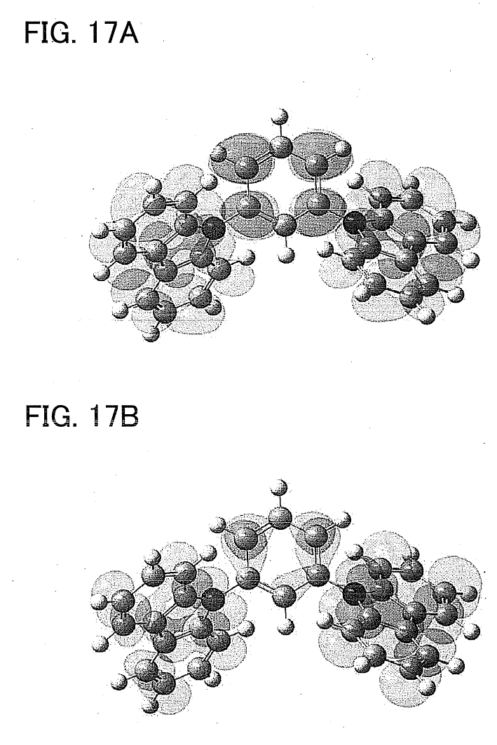

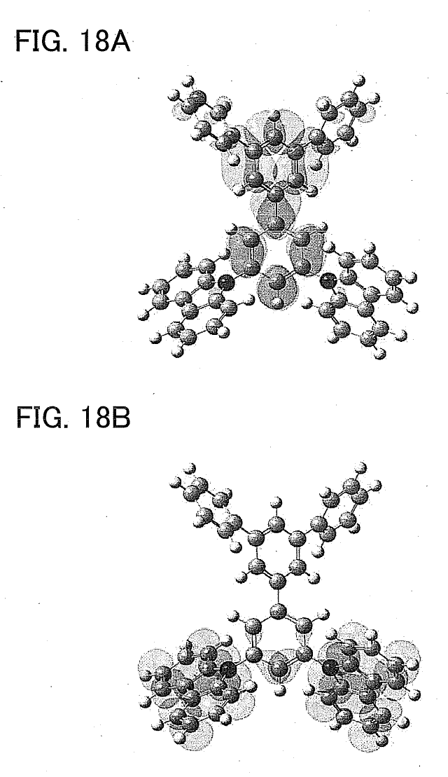

Distributions of the HOMOs and the LUMOs of mCP and mTPmCP were calculated by quantum chemistry calculation. The results are shown in FIGS. 17A and 17B and FIGS. 18A and 18B.

In the calculation, optimization of molecular structures was followed by analysis of the HOMO and LUMO of the optimized structure.

The density functional theory (DFT) using Gaussian basis was employed for the structure optimization. In the DFT, an exchange-correlation interaction is approximated by a functional (a function of a function) of one electron potential represented in terms of electron density to enable high-speed calculations. Here, B3LYP that is a hybrid functional was used to specify the weight of each parameter related to exchange-correlation energy. As a basis function, 6-311G (a basis function of a triple-split valence basis set using three contraction functions for each valence orbital) was applied to all the atoms. By the above basis function, for example, orbitals of 1s to 3s are considered in the case of hydrogen atoms while orbitals of 1s to 4s and 2p to 4p are considered in the case of nitrogen atoms. Furthermore, to improve calculation accuracy, the p function and the d function as polarization basis sets were added to hydrogen atoms and atoms other than hydrogen atoms, respectively, and the p orbital and the d orbital were considered.

Gaussian 09 was used as a quantum chemistry computational program. A high performance computer (manufactured by SGI Japan, Ltd., Altix 4700) was used for the calculations.

The HOMO and the LUMO in the most stable structure obtained by the calculation to optimize the structure of mCP are visualized by Gauss View 5.0.8 and shown in FIGS. 17A and 17B. Similarly, the HOMO and the LUMO in the most stable structure obtained by the calculation to optimize the structure of mTPmCP are visualized by Gauss View 5.0.8 and shown in FIGS. 18A and 18B. Note that the distributions of the LUMOs are shown in FIG. 17A and FIG. 18A and the distributions of the HOMOs are shown in FIG. 17B and FIG. 18B.

FIGS. 17A and 17B show that the HOMO and the LUMO of mCP, which is a hole-transport material in a hole-transport layer, are distributed mainly over a carbazole skeleton. FIGS. 18A and 18B show that the HOMO and LUMO of mTPmCP are distributed over a carbazole skeleton and the m-terphenyl skeleton, respectively.

In view of the above results, Light-emitting Element 1 in which mCP was used as a hole-transport material included in a hole-transport layer and mTPmCP was used as a host material included in a light-emitting layer was fabricated as an example of Embodiment 1 and evaluated. Note that Light-emitting Elements 2 to 4 were also fabricated and evaluated for comparison.

In this example, the fabricated light-emitting elements include emission center substances which emit blue phosphorescence. The molecular structures of the organic compounds used in this example are shown below.

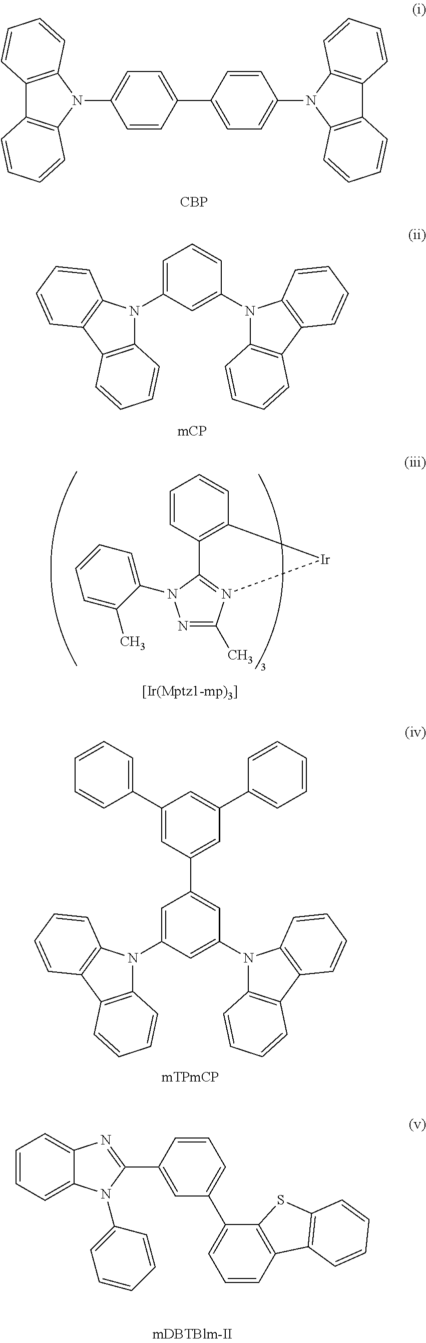

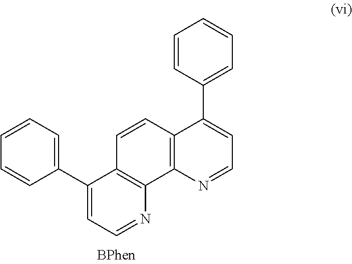 [SMILES: c1ccc(-c2ccnc3c2ccc2c(-c4ccccc4)ccnc23)cc1]

### [Fabrication of Light-Emitting Elements 1 to 4]

First, a glass substrate was prepared, over which indium tin oxide containing silicon (ITSO) with a thickness of 110 nm was formed as the first electrode 101. A surface of the ITSO film was covered with a polyimide film such that an area of 2 mm×2 mm of the surface was exposed, which corresponded to the electrode area. As a pretreatment for forming the light-emitting element over the substrate, the surface of the substrate was washed with water and baked at 200° C. for 1 hour, and then a UV ozone treatment was performed for 370 seconds. Then, the substrate was transferred into a vacuum evaporation apparatus in which the pressure was reduced to approximately 10⁻⁴ Pa, vacuum baking at 170° C. for 30 minutes was performed on the substrate in a heating chamber of the vacuum evaporation apparatus, and then the substrate was cooled down for approximately 30 minutes.

Then, the substrate was fixed on a holder provided in the vacuum evaporation apparatus such that the surface of the substrate provided with the first electrode 101 faced downward.

The pressure in the vacuum evaporation apparatus was reduced to 10⁻⁴ Pa, and then CBP represented by Structural Formula (i) above and molybdenum(VI) oxide were co-evaporated so that the weight ratio of CBP to molybdenum oxide was 2:1; thus, the hole-injection layer 111 was formed. The thickness was 80 nm. Note that a co-evaporation method is an evaporation method in which a plurality of different substances are concurrently vaporized from respective different evaporation sources.

Then, mCP represented by Structural Formula (ii) above was deposited by evaporation to a thickness of 20 nm for Light-emitting Element 1 and Light-emitting Element 2, and mTPmCP represented by Structural Formula (iv) above was deposited by evaporation to a thickness of 20 nm for Light-emitting Element 3 and Light-emitting Element 4; thus, the hole-transport layer 112 was formed in each of the light-emitting elements.

Further, for Light-emitting Element 1 and Light-emitting Element 4, the light-emitting layer 113 was formed on the hole-transport layer 112 by forming a stacked layer in such a way that mTPmCP and tris[3-methyl-1-(2-methylphenyl)-5-phenyl-1H-1,2,4-triazolato]iridium(III) (abbreviation: [Ir(Mptz1-mp)₃]) represented by Structural Formula (iii) above were deposited by evaporation to a thickness of 30 nm so that the weight ratio of mTPmCP to [Ir(Mptz1-mp)₃] was 1:0.08, and thereover, 2-[3-(dibenzothiophen-4-yl)phenyl]-1-phenyl-1H-benzimidazole (abbreviation: mDBTBIm-II) represented by Structural Formula (v) above and [Ir(Mptz1-mp)₃] were deposited by evaporation to a thickness of 10 nm so that the weight ratio of mDBTBIm-II to [Ir(Mptz1-mp)₃] was 1:0.08.

For Light-emitting Element 2 and Light-emitting Element 3, the light-emitting layer 113 was formed by foituing a stacked layer in such a way that mCP and [Ir(Mptz1-mp)₃] were deposited by evaporation to a thickness of 30 nm so that the weight ratio of mCP to [Ir(Mptz1-mp)₃] was 1:0.08, and thereover, mDBTBIm-II and [Ir(Mptz1-mp)₃] were then deposited by evaporation to a thickness of 10 nm so that the weight ratio of mDBTBIm-II to [Ir(Mptz1-mp)₃] was 1:0.08.

Next, BPhen represented by Structural Formula (vi) above was evaporated to form the electron-transport layer 114 with a thickness of 15 nm.

Further, lithium fluoride was evaporated to form the electron-injection layer 115 with a thickness of 1 nm over the electron-transport layer 114. Finally, a film of aluminum was formed to a thickness of 200 nm as the second electrode 102 serving as a cathode, whereby Light-emitting Elements 1 to 4 were completed. Note that in the above evaporation process, evaporation was all performed by a resistance heating method.

Light-emitting Element 1 completed is a light-emitting element as the example, which has the structure in Embodiment 1, and Light-emitting Elements 2 to 4 completed are light-emitting elements that are comparative examples. An element structure of each of the light-emitting elements is shown in a table below.

TABLE 1

| | Hole-injection | Hole-transport | | | Electron-transport | Electron-injection |
|---|---|---|---|---|---|---|
| | Layer | Layer | Light-emitting Layer | | Layer | Layer |
| | 80 nm | 20 nm | 30 nm | 10 nm | 15 nm | 1 nm |
| Light-emitting | CBP:MoOx | mCP | mTPmCP: | mDBTBIm-II: | BPhen | LiF |
| Element 1 | (4:2) | | Ir(Mptz1-mp)₃ | Ir(Mptz1-mp)₃ | | |
| | | | (1:0.08) | (1:0.08) | | |
| Light-emitting | CBP:MoOx | mCP | mCP: | mDBTBIm-II: | BPhen | LiF |
| Element 2 | (4:2) | | Ir(Mptz1-mp)₃ | Ir(Mptz1-mp)₃ | | |
| | | | (1:0.08) | (1:0.08) | | |
| Light-emitting | CBP:MoOx | mTPmCP | mCP: | mDBTBIm-II: | BPhen | LiF |
| Element 3 | (4:2) | | Ir(Mptz1-mp)₃ | Ir(Mptz1-mp)₃ | | |
| | | | (1:0.08) | (1:0.08) | | |
| Light-emitting | CBP:MoOx | mTPmCP | mTPmCP: | mDBTBIm-II: | BPhen | LiF |
| Element 4 | (4:2) | | Ir(Mptz1-mp)₃ | Ir(Mptz1-mp)₃ | | |
| | | | (1:0.08) | (1:0.08) | | |

### [Operation Characteristics of Light-Emitting Elements 1 to 4]

The thus obtained Light-emitting Elements 1 to 4 were put into a glove box under a nitrogen atmosphere, and the light-emitting elements were sealed so as not to be exposed to the air. Then, the operation characteristics of the light-emitting elements were measured. Note that the measurements were carried out at room temperature (in an atmosphere kept at 25° C.).

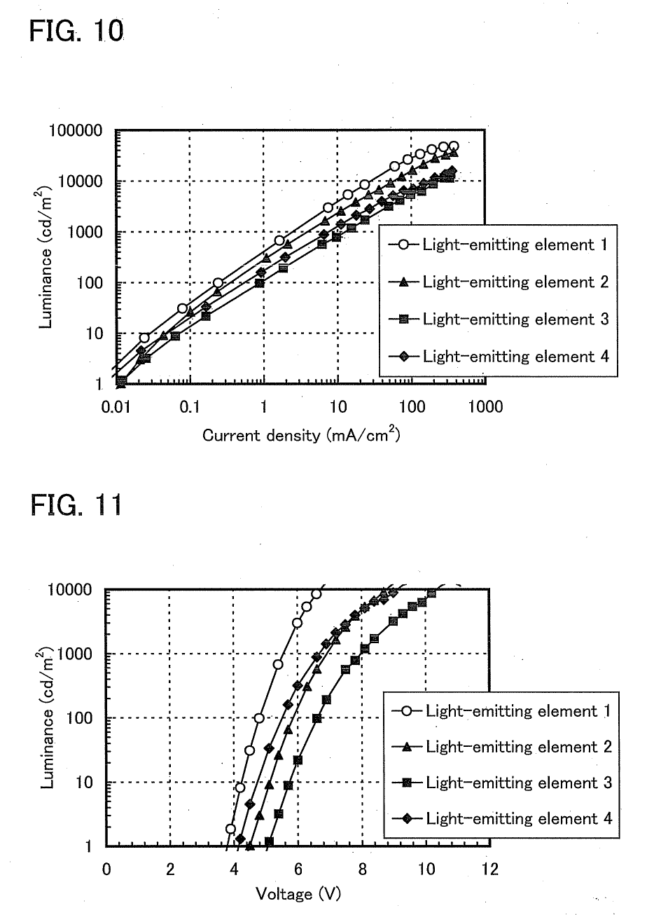

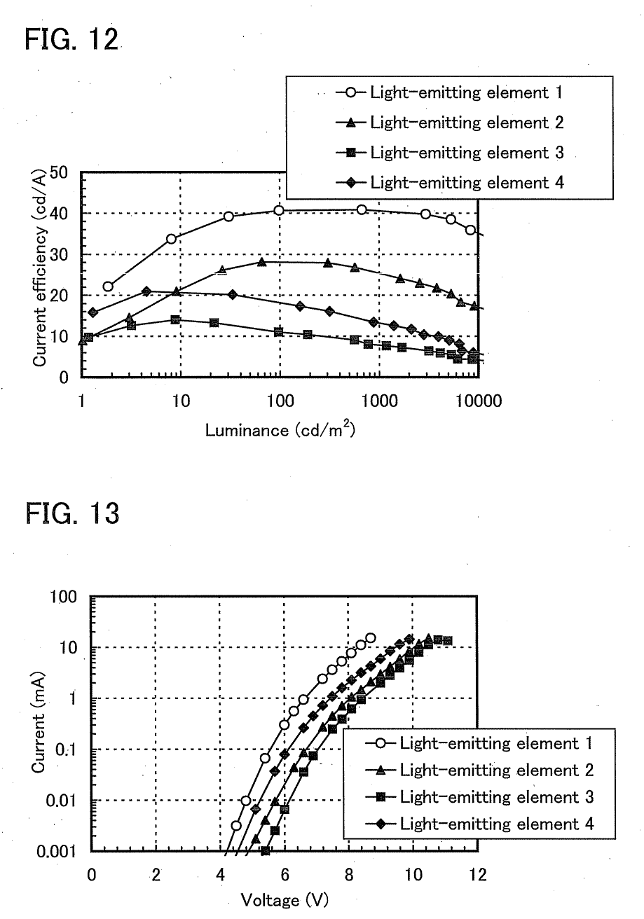

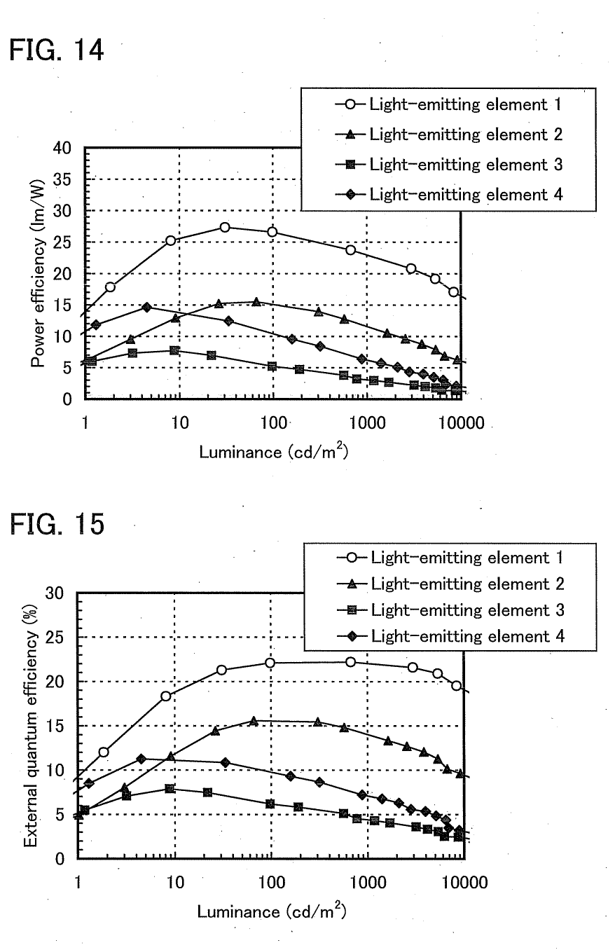

FIG. 10 shows current density-luminance characteristics of Light-emitting Elements 1 to 4, FIG. 11 shows voltage-luminance characteristics of Light-emitting Elements 1 to 4, FIG. 12 shows luminance-current efficiency characteristics of Light-emitting Elements 1 to 4, FIG. 13 shows voltage-current characteristics of Light-emitting Elements 1 to 4, FIG. 14 shows luminance-power efficiency characteristics of Light-emitting Elements 1 to 4, and FIG. 15 shows luminance-external quantum efficiency characteristics of Light-emitting Elements 1 to 4. In FIG. 10, the vertical axis represents luminance (cd/m²) and the horizontal axis represents current density (mA/cm²). In FIG. 11, the vertical axis represents luminance (cd/m²), and the horizontal axis represents voltage (V). In FIG. 12, the vertical axis represents current efficiency (cd/A), and the horizontal axis represents luminance (cd/m²). In FIG. 13, the vertical axis represents current (mA), and the horizontal axis represents voltage (V). In FIG. 14, the vertical axis represents power efficiency (lm/W), and the horizontal axis represents luminance (cd/m²). In FIG. 15, the vertical axis represents external quantum efficiency (%), and the horizontal axis represents luminance (cd/m²).

FIG. 12, FIG. 14, and FIG. 15 show that Light-emitting Element 1 as the example has extremely high luminance-current efficiency characteristics, luminance-power efficiency characteristics, and luminance-external quantum efficiency characteristics as compared to Light-emitting Elements 2 to 4, meaning that Light-emitting Element 1 has high emission efficiency. Moreover, FIG. 11 and FIG. 13 show that Light-emitting Element 1 has high voltage-luminance characteristics and voltage-current characteristics, leading to a conclusion that Light-emitting Element 1 has low driving voltage.

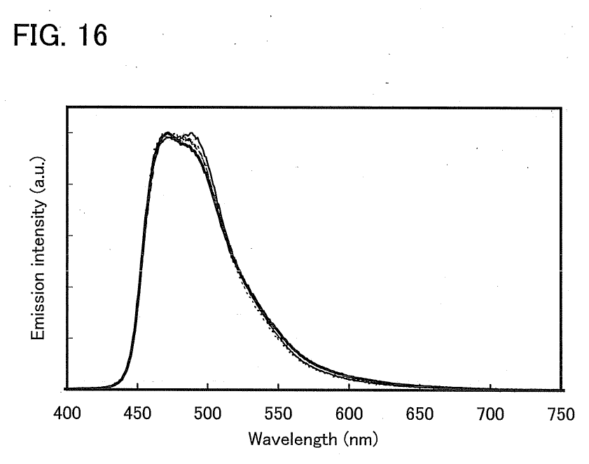

FIG. 16 shows normalized emission spectra of fabricated Light-emitting Elements 1 to 4 when a current of 0.1 mA was made to flow therein. As can be seen in FIG. 16, the emission spectra mostly overlap with each other, and Light-emitting Elements 1 to 4 emit blue light originating from the emission center substance [Ir(Mptz1-mp)₃]. Note that in FIG. 16, the bold solid line shows the spectrum of Light-emitting Element 1 as the example.

A table below summarizes main characteristics of Light-emitting Elements 1 to 4 at around 1000 cd/m².

TABLE 2

| | Volt- | | | Current | Power | Quantum |
|---|---|---|---|---|---|---|
| | age | Chromaticity | | Efficiency | Efficiency | Efficiency |
| | (V) | x | y | (cd/A) | (lm/W) | (%) |
| Light-emitting | 5.4 | 0.16 | 0.30 | 40.8 | 23.8 | 22.2 |
| Element 1 | | | | | | |
| Light-emitting | 6.6 | 0.16 | 0.30 | 26.8 | 12.8 | 14.8 |
| Element 2 | | | | | | |
| Light-emitting | 8.1 | 0.16 | 0.29 | 7.7 | 3.0 | 4.3 |
| Element 3 | | | | | | |
| Light-emitting | 6.6 | 0.17 | 0.30 | 13.4 | 6.4 | 7.2 |
| Element 4 | | | | | | |

Thus, Light-emitting Element 1 according to Embodiment 1 was found to have high emission efficiency. It was also found that Light-emitting Element 1 is a light-emitting element with low driving voltage. Here, comparison between Light-emitting Elements 1 and 2 reveals that only the hole-transport material (mCP) and the host material (mTPmCP) in the light-emitting layer are interchanged with each other. Additionally, the structures of these materials are quite similar to each other. In other words, the structures of Light-emitting Elements 1 and 2 are almost the same. However, as mentioned above, an extremely large difference in characteristics is observed therebetween. Hence, emphasis should be placed on the unique concept of the present invention that fabrication of an EL element utilizing the difference in the distributions of the HOMO and LUMO between the structurally quite similar materials enables a drastic improvement of the element characteristics.

### Example 2

In this example, a light-emitting element including an emission center substance which emits blue phosphorescence was fabricated with the use of mCP as a hole-transport material included in a hole-transport layer and 3,5-bis[3-(9H-carbazol-9-yl)phenyl]pyridine (abbreviation: 35DCzPPy) as a host material included in a light-emitting layer. Note that mCP is a substance whose HOMO and LUMO are both distributed over a carbazole skeleton, and 35DCzPPy is a substance whose HOMO is distributed over a carbazole skeleton and whose LUMO is not distributed over the carbazole skeleton but is distributed over another skeleton. The molecular structures of the organic compounds used in this example are shown below.

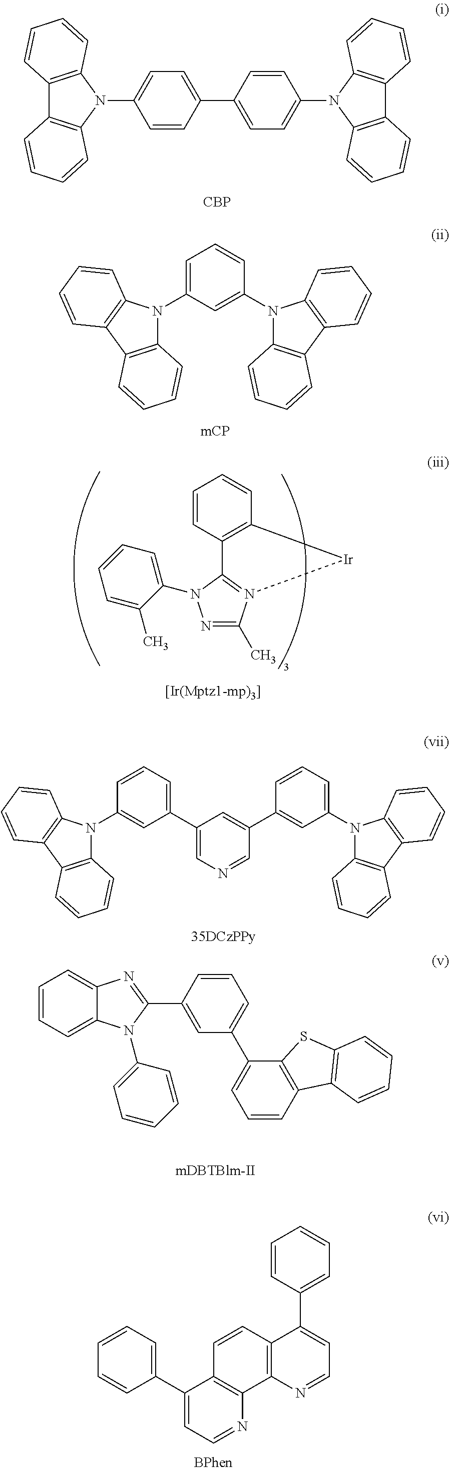

### [Fabrication of Light-Emitting Elements 5 to 8]

First, a glass substrate was prepared, over which indium tin oxide containing silicon (ITSO) with a thickness of 110 nm was formed as the first electrode 101. A surface of the ITSO film was covered with a polyimide film such that an area of 2 mm×2 mm of the surface was exposed, which corresponded to the electrode area. As a pretreatment for forming the light-emitting element over the substrate, the surface of the substrate was washed with water and baked at 200° C. for 1 hour, and then a UV ozone treatment was performed for 370 seconds. Then, the substrate was transferred into a vacuum evaporation apparatus in which the pressure was reduced to approximately 10⁻⁴ Pa, vacuum baking at 170° C. for 30 minutes was performed on the substrate in a heating chamber of the vacuum evaporation apparatus, and then the substrate was cooled down for approximately 30 minutes.

Then, the substrate was fixed on a holder provided in the vacuum evaporation apparatus such that the surface of the substrate provided with the first electrode 101 faced downward.

The pressure in the vacuum evaporation apparatus was reduced to 10⁻⁴ Pa, and then CBP represented by Structural Formula (i) above and molybdenum(VI) oxide were co-evaporated so that the weight ratio of CBP to molybdenum oxide was 2:1; thus, the hole-injection layer 111 was formed. The thickness was 80 nm.

Then, mCP represented by Structural Formula (ii) above was deposited by evaporation to a thickness of 20 nm for Light-emitting Element 5 and Light-emitting Element 6, and 35DCzPPy represented by Structural Formula (vii) above was deposited by evaporation to a thickness of 20 nm for Light-emitting Element 7 and Light-emitting Element 8; thus, the hole-transport layer 112 was formed in each of the light-emitting elements.

Further, for Light-emitting Element 5 and Light-emitting Element 8, the light-emitting layer 113 was formed on the hole-transport layer 112 by forming a stacked layer in such a way that 35DCzPPy and [Ir(Mptz1-mp)₃] represented by Structural Formula (iii) above were deposited by evaporation to a thickness of 30 nm so that the weight ratio of 35DCzPPy to [Ir(Mptz1-mp)₃] was 1:0.08, and thereover, mDBTBIm-II represented by Structural Formula (v) above and [Ir(Mptz1-mp)₃] were deposited by evaporation to a thickness of 10 nm so that the weight ratio of mDBTBIm-II to [Ir(Mptz1-mp)₃] was 1:0.08.

For Light-emitting Element 6 and Light-emitting Element 7, the light-emitting layer 113 was formed by forming a stacked layer in such a way that mCP and [Ir(Mptz1-mp)₃] were deposited by evaporation to a thickness of 30 nm so that the weight ratio of mCP to [Ir(Mptz1-mp)₃] was 1:0.08, and thereover, mDBTBIm-II and [Ir(Mptz1-mp)₃] were then deposited by evaporation to a thickness of 10 nm so that the weight ratio of mDBTBIm-II to [Ir(Mptz1-mp)₃] was 1:0.08.

Next, BPhen represented by Structural Formula (vi) above was evaporated to form the electron-transport layer 114 with a thickness of 15 nm.

Further, lithium fluoride was evaporated to form the electron-injection layer 115 with a thickness of 1 nm over the electron-transport layer 114. Finally, a film of aluminum was formed to a thickness of 200 nm as the second electrode 102 serving as a cathode, whereby Light-emitting Elements 5 to 8 were completed. Note that in the above evaporation process, evaporation was all performed by a resistance heating method.

Light-emitting Element 5 completed is a light-emitting element as the example, which has the structure in Embodiment 1, and Light-emitting Elements 6 to 8 completed are light-emitting elements that are comparative examples. An element structure of each of the light-emitting elements is summarized in a table below.

TABLE 3

| | Hole-injection | Hole-transport | | | Electron-transport | Electron-injection |
|---|---|---|---|---|---|---|
| | Layer | Layer | Light-emitting Layer | | Layer | Layer |
| | 80 nm | 20 nm | 30 nm | 10 nm | 15 nm | 1 nm |
| Light-emitting | CBP:MoOx | mCP | 35DCzPPy: | mDBTBIm-II: | BPhen | LiF |
| Element 5 | (4:2) | | Ir(Mptz1-mp)₃ | Ir(Mptz1-mp)₃ | | |
| | | | (1:0.08) | (1:0.08) | | |
| Light-emitting | CBP:MoOx | mCP | mCP: | mDBTBIm-II: | BPhen | LiF |
| Element 6 | (4:2) | | Ir(Mptz1-mp)₃ | Ir(Mptz1-mp)₃ | | |
| | | | (1:0.08) | (1:0.08) | | |
| Light-emitting | CBP:MoOx | 35DCzPPy | mCP: | mDBTBIm-II: | BPhen | LiF |
| Element 7 | (4:2) | | Ir(Mptz1-mp)₃ | Ir(Mptz1-mp)₃ | | |
| | | | (1:0.08) | (1:0.08) | | |
| Light-emitting | CBP:MoOx | 35DCzPPy | 35DCzPPy: | mDBTBIm-II: | BPhen | LiF |
| Element 8 | (4:2) | | Ir(Mptz1-mp)₃ | Ir(Mptz1-mp)₃ | | |
| | | | (1:0.08) | (1:0.08) | | |

### [Operation Characteristics of Light-Emitting Elements 5 to 8]

The thus obtained Light-emitting Elements 5 to 8 were put into a glove box under a nitrogen atmosphere, and the light-emitting elements were sealed so as not to be exposed to the air. Then, the operation characteristics of the light-emitting elements were measured. Note that the measurements were carried out at room temperature (in an atmosphere kept at 25° C.).

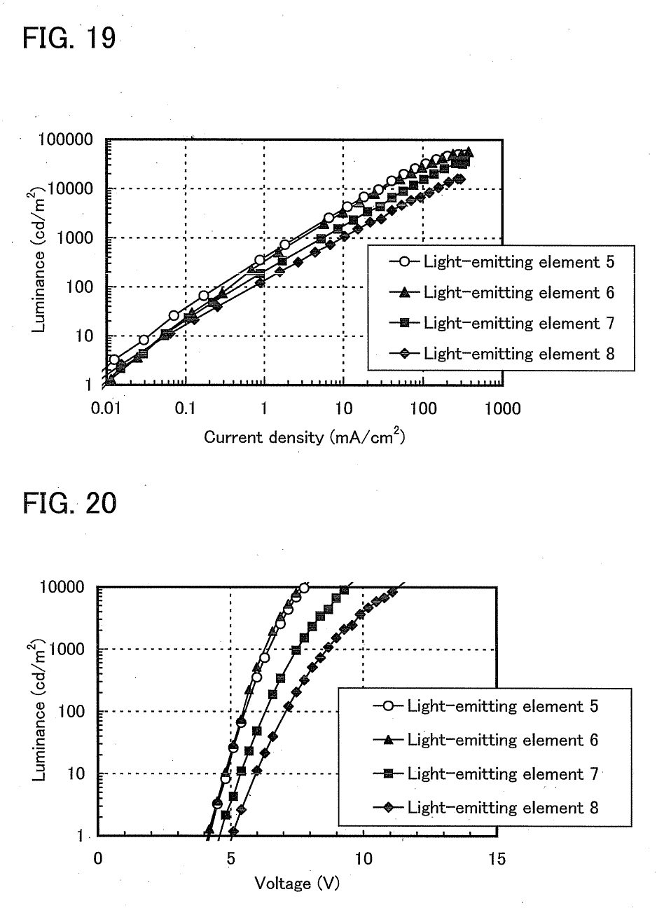

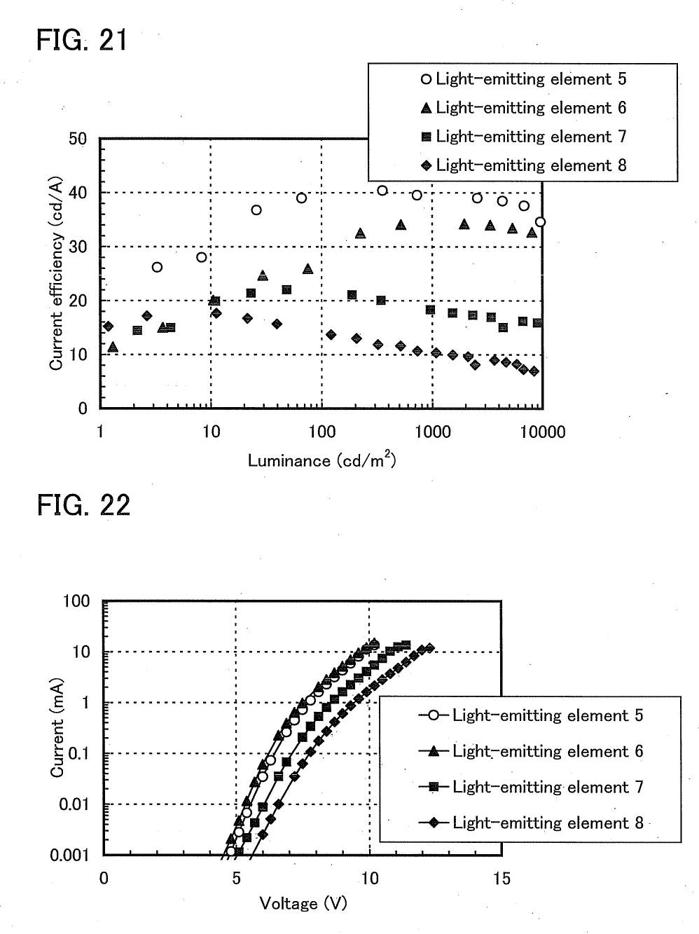

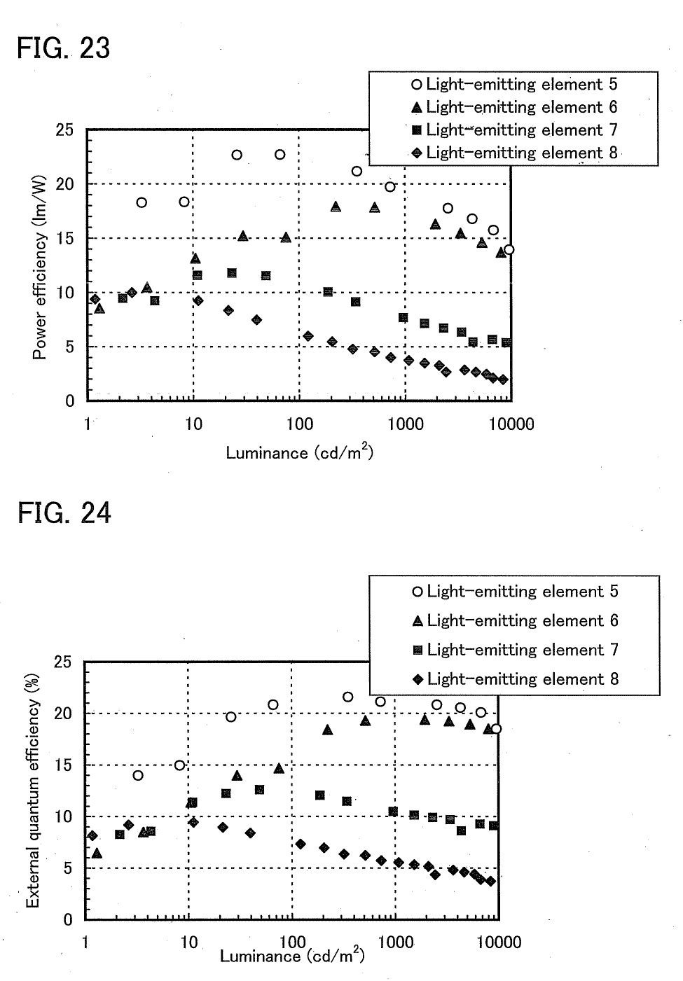

FIG. 19 shows current density-luminance characteristics of Light-emitting Elements 5 to 8, FIG. 20 shows voltage-luminance characteristics of Light-emitting Elements 5 to 8, FIG. 21 shows luminance-current efficiency characteristics of Light-emitting Elements 5 to 8, FIG. 22 shows voltage-current characteristics of Light-emitting Elements 5 to 8, FIG. 23 shows luminance-power efficiency characteristics of Light-emitting Elements 5 to 8, and FIG. 24 shows luminance-external quantum efficiency characteristics of Light-emitting Elements 5 to 8. In these figures, the definition of the axes is identical to that of FIGS. 10 to 15.

FIG. 21, FIG. 23, and FIG. 24 show that Light-emitting Element 5 as the example has extremely high luminance-current efficiency characteristics, luminance-power efficiency characteristics, and luminance-external quantum efficiency characteristics as compared to Light-emitting Elements 6 to 8, meaning that Light-emitting Element 5 has high emission efficiency. Moreover, FIG. 20 and FIG. 22 show that Light-emitting Element 5 has high voltage-luminance characteristics and voltage-current characteristics, leading to a conclusion that Light-emitting Element 5 has low driving voltage.

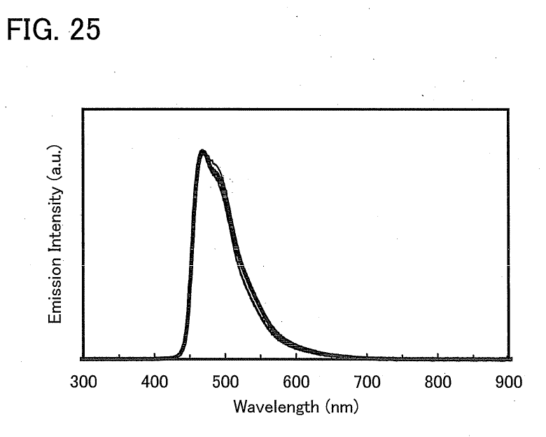

FIG. 25 shows normalized emission spectra of fabricated Light-emitting Elements 5 to 8 when a current of 0.1 mA was made to flow therein. As can be seen in FIG. 25, the emission spectra mostly overlap with each other, and Light-emitting Elements 5 to 8 emit blue light originating from the emission center substance [Ir(Mptz1-mp)₃]. Note that in FIG. 25, the bold solid line shows the spectrum of Light-emitting Element 5 as the example.

A table below summarizes main characteristics of Light-emitting Elements 5 to 8 at around 1000 cd/m².

TABLE 4

| | Volt- | | | Current | Power | Quantum |
|---|---|---|---|---|---|---|
| | age | Chromaticity | | Efficiency | Efficiency | Efficiency |
| | (V) | x | y | (cd/A) | (lm/W) | (%) |
| Light-emitting | 6.3 | 0.17 | 0.30 | 39.6 | 19.7 | 21.1 |
| Element 5 | | | | | | |
| Light-emitting | 6.0 | 0.17 | 0.28 | 34.1 | 17.9 | 19.3 |
| Element 6 | | | | | | |
| Light-emitting | 7.5 | 0.17 | 0.28 | 18.3 | 7.7 | 10.5 |
| Element 7 | | | | | | |
| Light-emitting | 8.7 | 0.17 | 0.30 | 10.3 | 3.7 | 5.5 |
| Element 8 | | | | | | |

As described above, Light-emitting Element 5 according to Embodiment 1 was found to have high emission efficiency. It was also found that Light-emitting Element 5 has low power consumption.

### Reference Example 1

A synthesis example of [Ir(Mptz1-mp)₃] which is a material used in the example, will be described.

### Step 1: Synthesis of N-(1-Ethoxyethylidene)benzamide

First, 15.5 g of ethyl acetimidate hydrochloride, 150 mL of toluene, and 31.9 g of triethylamine (Et₃N) were put into a 500-mL three-neck flask and stirred at room temperature for 10 minutes. With a 50-mL dropping funnel, a solution of 17.7 g of benzoyl chloride in 30 mL of toluene was added dropwise to this mixture, and the mixture was stirred at room temperature for 24 hours. After the reaction, the reaction mixture was suction-filtered, and the solid was washed with toluene. The obtained filtrate was concentrated to give N-(1-ethoxyethylidene)benzamide (a red oily substance, 82% yield). A synthesis scheme of Step 1 is shown below.

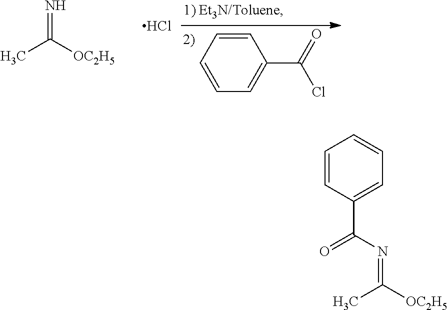

### Step 2: Synthesis of 3-Methyl-1-(2-methylphenyl)-5-phenyl-1H-1,2,4-triazole (abbreviation: HMptz1-mp)

Next, into a 300-mL recovery flask were put 8.68 g of o-tolylhydrazine hydrochloride, 100 mL of carbon tetrachloride, and 35 mL of triethylamine (Et₃N), and the mixture was stirred at room temperature for 1 hour. After the reaction, 8.72 g of N-(1-ethoxyethylidene)benzamide obtained in the above Step 1 was added to this mixture, and the mixture was stirred at room temperature for 24 hours. After the reaction, water was added to the reaction mixture, and the aqueous layer was subjected to extraction with chloroform. The organic layer of the resulting mixture was washed with saturated brine, and dried with anhydrous magnesium sulfate added thereto. The obtained mixture was gravity-filtered, and the filtrate was concentrated to give an oily substance. The obtained oily substance was purified by silica gel column chromatography. Dichloromethane was used as a developing solvent. The obtained fraction was concentrated to give HMptz1-mp (an orange oily substance, 84% yield). A synthesis scheme of Step 2 is shown below.

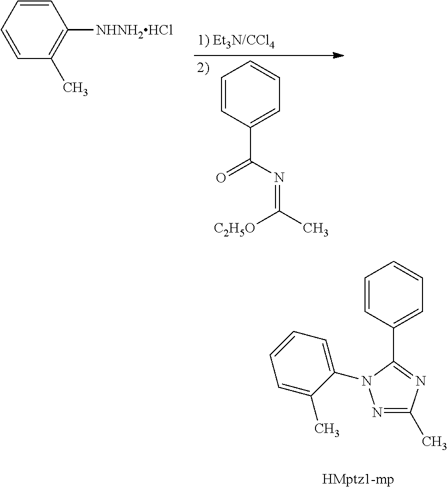

### Step 3: Synthesis of [Ir(Mptz1-mp)₃]

Next, 2.71 g of the ligand HMptz1-mp obtained in the above Step 2 and 1.06 g of tris(acetylacetonato)iridium(III) were put into a reaction container provided with a three-way cock. The air in this flask was replaced with argon, and heated at 250° C. for 48 hours. This reaction mixture was dissolved in dichloromethane and purified by silica gel column chromatography. As the developing solvent, dichloromethane was first used, and a mixed solvent of dichloromethane and ethyl acetate in a ratio of 10:1 (v/v) was then used. The obtained fraction was concentrated to give a solid. This solid was washed with ethyl acetate, and recrystallized from a mixed solvent of dichloromethane and ethyl acetate to give the organometallic complex [Ir(Mptz1-mp)₃] (a yellow powder, 35% yield). A synthesis scheme of Step 3 is shown below.

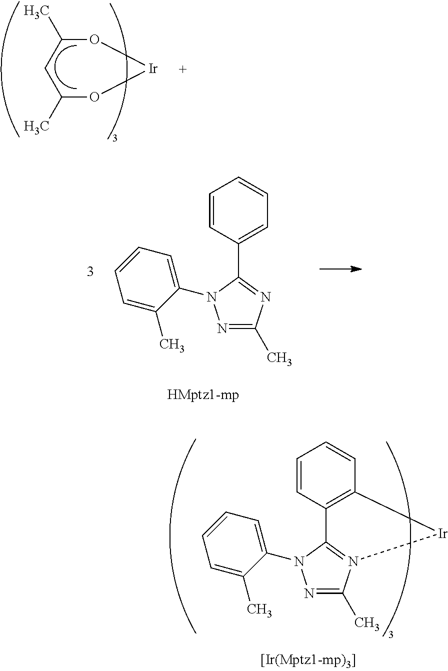

Analysis results by nuclear magnetic resonance spectroscopy (¹H-NMR) of the yellow powder obtained in the above Step 3 are shown below. The results show that [Ir(Mptz1-mp)₃] was obtained.

¹H NMR data of the obtained substance are as follows: ¹H NMR. δ (CDCl₃): 1.94-2.21 (m, 18H), 6.47-6.76 (m, 12H), 7.29-7.52 (m, 12H).

### Reference Example 2

A synthesis example of mDBTBIm-II) which was a material used in the example, will be described.

### Synthesis of mDBTBIm-II

Into a 50-mL three-neck flask were put 1.2 g (3.3 mmol) of 2-(3-bromophenyl)-1-phenyl-1H-benzimidazole, 0.8 g (3.3 mmol) of dibenzothiophene-4-boronic acid, and 50 mg (0.2 mmol) of tri(ortho-tolyl)phosphine. The air in the flask was replaced with nitrogen. To this mixture were added 3.3 mL of a 2.0 mmol/L aqueous solution of potassium carbonate, 12 mL of toluene, and 4 mL of ethanol. Under reduced pressure, this mixture was stirred to be degassed. Then, 7.4 mg (33 μmol) of palladium(II) acetate was added to this mixture, and the mixture was stirred at 80° C. for 6 hours under a nitrogen stream. After the reaction, the aqueous layer of the obtained mixture was subjected to extraction with toluene. The obtained solution of the extract and the organic layer were combined, washed with saturated brine, and then dried with magnesium sulfate. This mixture was separated by gravity filtration, and the filtrate was concentrated to give an oily substance. This oily substance was purified by silica gel column chromatography. The silica gel column chromatography was carried out using toluene as a developing solvent. The obtained fraction was concentrated to give an oily substance. This oily substance was purified by high performance liquid chromatography. The high performance liquid chromatography was performed using chloroform as a developing solvent. The obtained fraction was concentrated to give an oily substance. This oily substance was diluted in a mixed solvent of toluene and hexane to allow a precipitate to be formed, so that the objective substance was obtained as 0.8 g of a pale yellow powder in 51% yield. The synthesis scheme is illustrated in the following formula.

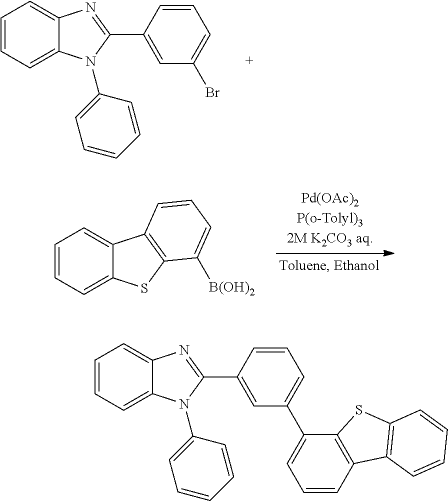 [SMILES: Brc1cccc(-c2nc3ccccc3n2-c2ccccc2)c1 ; OB(O)c1cccc2c1sc1ccccc12 ; c1ccc(-n2c(-c3cccc(-c4cccc5c4sc4ccccc45)c3)nc3ccccc32)cc1]

By a train sublimation method, 0.8 g of the obtained pale yellow powder was purified. In the purification, the pale yellow powder was heated at 215° C. under a pressure of 3.0 Pa with a flow rate of argon gas of 5 mL/min. After the purification, 0.6 g of a white powder of the substance which was the object of the synthesis was obtained in 82% yield.

This compound was identified as mDBTBIm-II, which was the object of the synthesis, by nuclear magnetic resonance (NMR) spectroscopy.

¹H NMR data of the obtained compound are as follows: ¹H NMR (CDCl₃, 300 MHz): δ (ppm)=7.23-7.60 (m, 13H), 7.71-7.82 (m, 3H), 7.90-7.92 (m, 2H), 8.10-8.17 (m, 2H).

This application is based on Japanese Patent Application serial no. 2011-149643 filed with Japan Patent Office on Jul. 6, 2011, the entire contents of which are hereby incorporated by reference.

What is claimed is:

1. A light-emitting device comprising:
an anode;
a hole-transport layer over the anode, the hole-transport layer comprising a first carbazole derivative;
a light-emitting layer over the hole-transport layer, the light-emitting layer comprising a second carbazole derivative and an emission substance dispersed in the second carbazole derivative; and
a cathode over the light-emitting layer,
wherein the first carbazole derivative consists of a first carbazole skeleton and a skeleton other than the first carbazole skeleton,
wherein the second carbazole derivative consists of a second carbazole skeleton and a skeleton other than the second carbazole skeleton,
wherein both a highest occupied molecular orbital and a lowest unoccupied molecular orbital of the first carbazole derivative are more widely spread over the first carbazole skeleton than the skeleton other than the first carbazole skeleton,
wherein a highest occupied molecular orbital of the second carbazole derivative is more widely spread over the second carbazole skeleton than the skeleton other than the second carbazole skeleton, and
wherein the lowest unoccupied molecular orbital of the second carbazole derivative is more widely spread over the skeleton other than the second carbazole skeleton than the second carbazole skeleton.

2. The light-emitting device according to claim 1, wherein the emission substance is a phosphorescent material.

3. The light-emitting device according to claim 1, wherein the emission substance is a blue emissive phosphorescent material.

4. The light-emitting device according to claim 1, wherein the skeleton other than the second carbazole skeleton of the second carbazole derivative comprises a skeleton having an electron-transport property.

5. The light-emitting device according to claim 4, wherein the skeleton having an electron-transport property is selected from an aromatic hydrocarbon group and a π-electron deficient heteroaromatic group.

6. The light-emitting device according to claim 1, wherein the first carbazole derivative is selected from compounds represented by formulae (100) to (107):

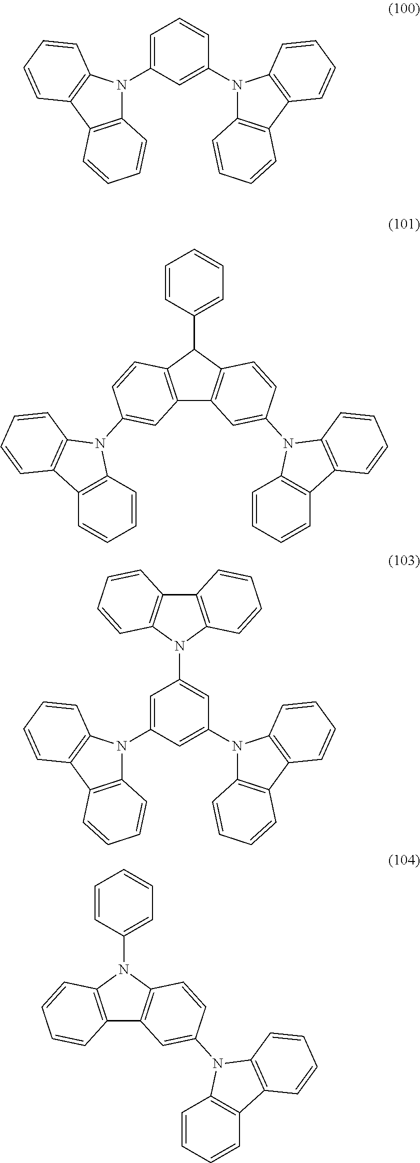

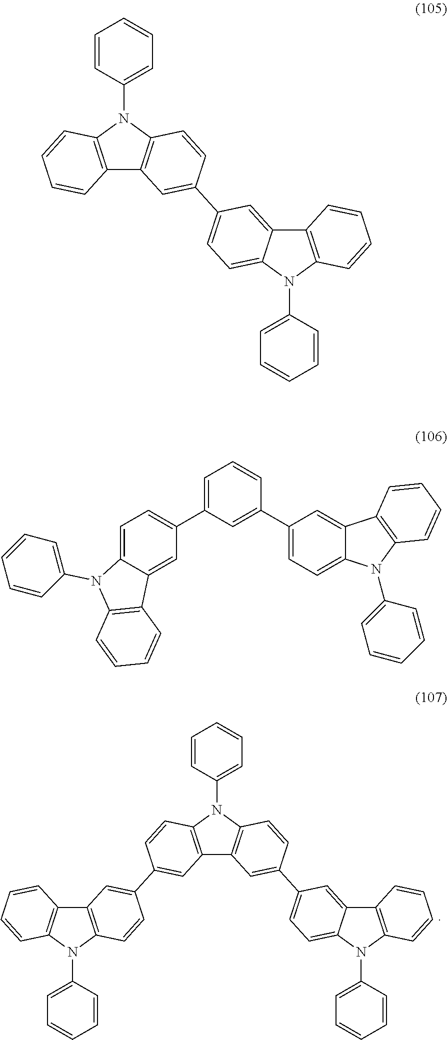 [SMILES: c1ccc(-n2c3ccccc3c3cc(-c4ccc5c(c4)c4ccccc4n5-c4ccccc4)ccc32)cc1 ; c1ccc(-n2c3ccccc3c3cc(-c4cccc(-c5ccc6c(c5)c5ccccc5n6-c5ccccc5)c4)ccc32)cc1 ; c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1]

7. The light-emitting device according to claim 1, wherein the second carbazole derivative is selected from compounds represented by formula (200) to (220):

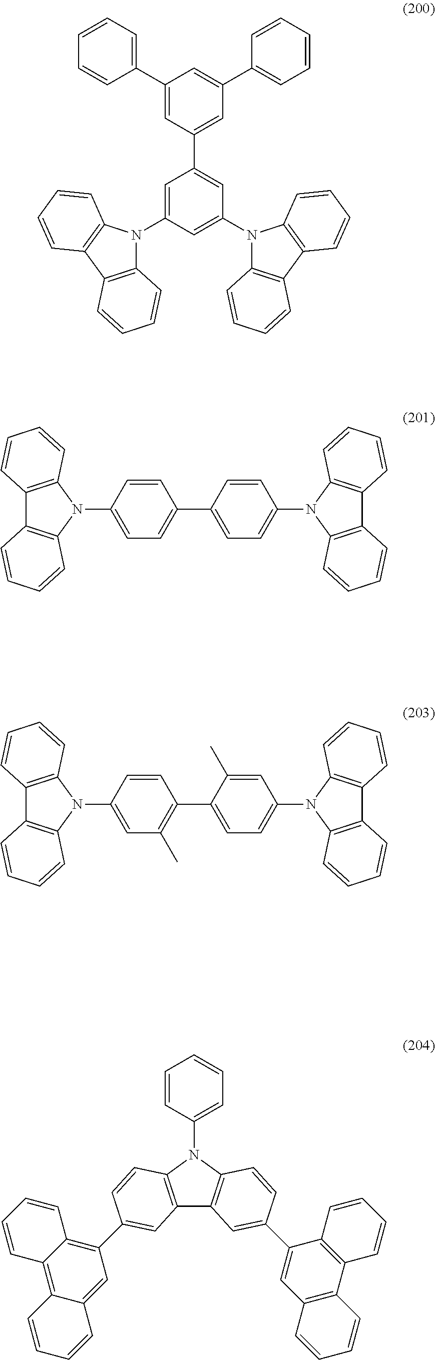 [SMILES: c1ccc(-c2cc(-c3ccccc3)cc(-c3cc(-n4c5ccccc5c5ccccc54)cc(-n4c5ccccc5c5ccccc54)c3)c2)cc1 ; c1ccc2c(c1)c1ccccc1n2-c1ccc(-c2ccc(-n3c4ccccc4c4ccccc43)cc2)cc1 ; Cc1cc(-n2c3ccccc3c3ccccc32)ccc1-c1ccc(-n2c3ccccc3c3ccccc32)cc1C ; c1ccc(-n2c3ccc(-c4cc5ccccc5c5ccccc45)cc3c3cc(-c4cc5ccccc5c5ccccc45)ccc32)cc1]

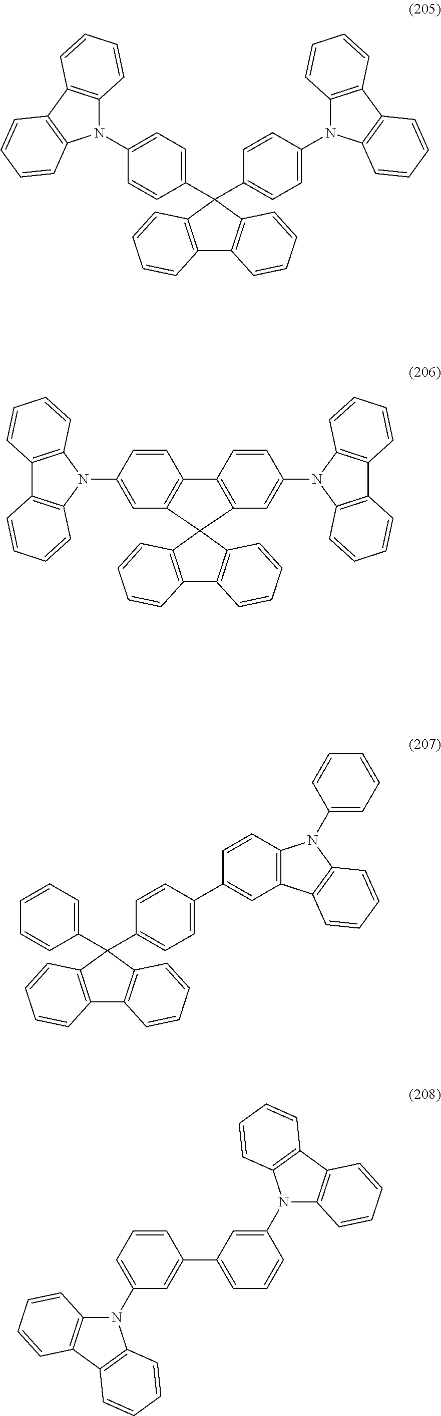 [SMILES: c1ccc2c(c1)-c1ccccc1C2(c1ccc(-n2c3ccccc3c3ccccc32)cc1)c1ccc(-n2c3ccccc3c3ccccc32)cc1 ; c1ccc2c(c1)-c1ccccc1C21c2cc(-n3c4ccccc4c4ccccc43)ccc2-c2ccc(-n3c4ccccc4c4ccccc43)cc21 ; c1ccc(-n2c3ccccc3c3cc(-c4ccc(C5(c6ccccc6)c6ccccc6-c6ccccc65)cc4)ccc32)cc1 ; c1cc(-c2cccc(-n3c4ccccc4c4ccccc43)c2)cc(-n2c3ccccc3c3ccccc32)c1]

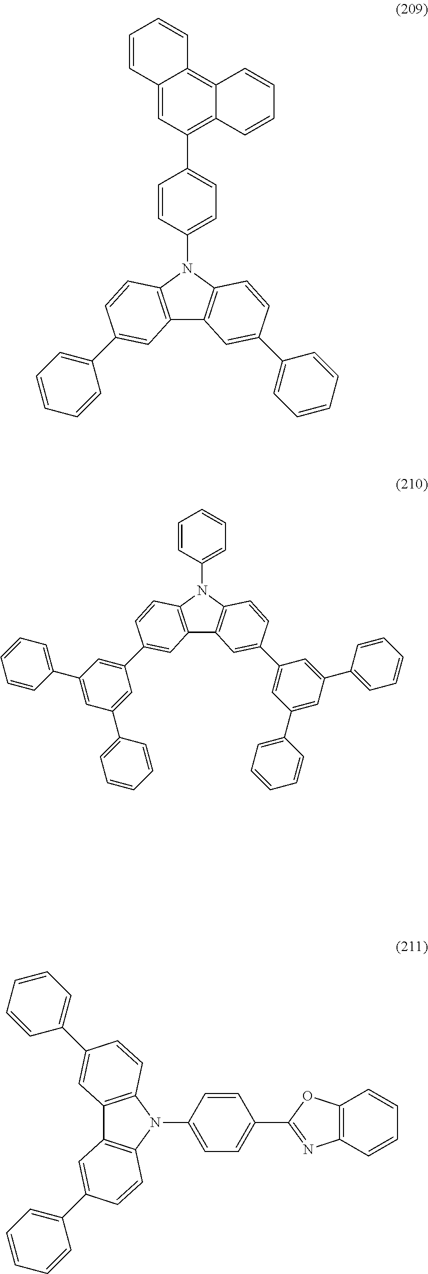 [SMILES: c1ccc(-c2ccc3c(c2)c2cc(-c4ccccc4)ccc2n3-c2ccc(-c3cc4ccccc4c4ccccc34)cc2)cc1 ; c1ccc(-c2cc(-c3ccccc3)cc(-c3ccc4c(c3)c3cc(-c5cc(-c6ccccc6)cc(-c6ccccc6)c5)ccc3n4-c3ccccc3)c2)cc1 ; c1ccc(-c2ccc3c(c2)c2cc(-c4ccccc4)ccc2n3-c2ccc(-c3nc4ccccc4o3)cc2)cc1]

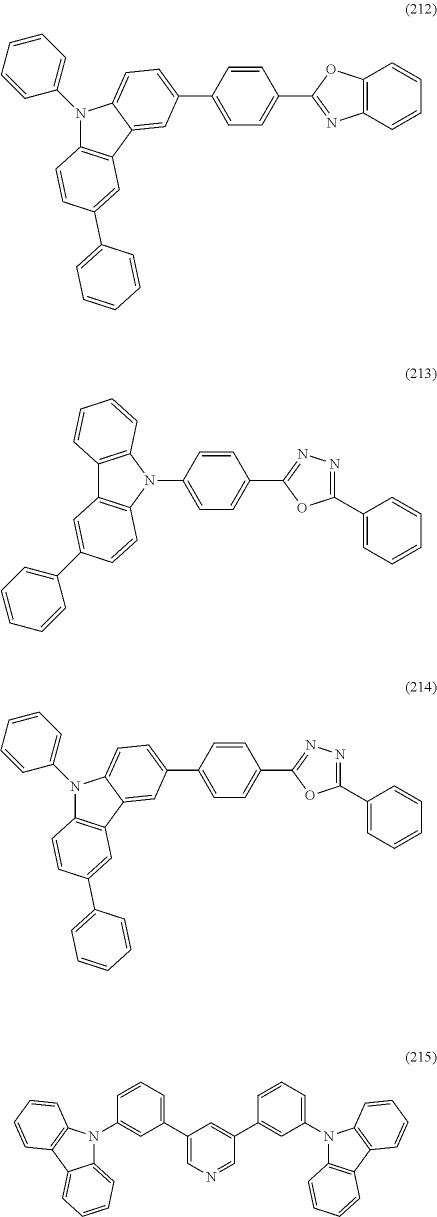 [SMILES: c1ccc(-c2ccc3c(c2)c2cc(-c4ccc(-c5nc6ccccc6o5)cc4)ccc2n3-c2ccccc2)cc1 ; c1ccc(-c2ccc3c(c2)c2ccccc2n3-c2ccc(-c3nnc(-c4ccccc4)o3)cc2)cc1 ; c1ccc(-c2ccc3c(c2)c2cc(-c4ccc(-c5nnc(-c6ccccc6)o5)cc4)ccc2n3-c2ccccc2)cc1 ; c1cc(-c2cncc(-c3cccc(-n4c5ccccc5c5ccccc54)c3)c2)cc(-n2c3ccccc3c3ccccc32)c1]

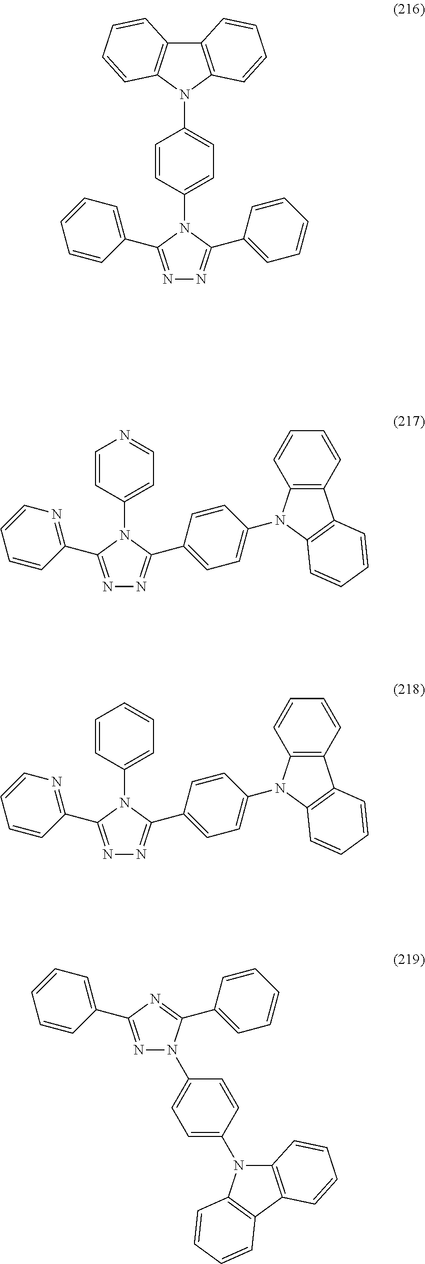 [SMILES: c1ccc(-c2nnc(-c3ccccc3)n2-c2ccc(-n3c4ccccc4c4ccccc43)cc2)cc1 ; c1ccc(-c2nnc(-c3ccc(-n4c5ccccc5c5ccccc54)cc3)n2-c2ccncc2)nc1 ; c1ccc(-n2c(-c3ccc(-n4c5ccccc5c5ccccc54)cc3)nnc2-c2ccccn2)cc1 ; c1ccc(-c2nc(-c3ccccc3)n(-c3ccc(-n4c5ccccc5c5ccccc54)cc3)n2)cc1]

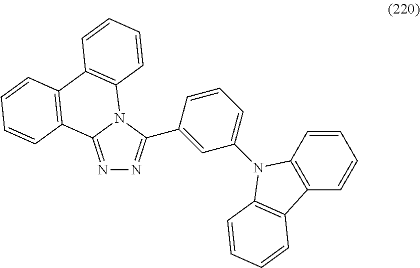 [SMILES: c1cc(-c2nnc3c4ccccc4c4ccccc4n23)cc(-n2c3ccccc3c3ccccc32)c1]

8. The light-emitting device according to claim 1,
wherein the first carbazole derivative is a compound represented by formula (100): 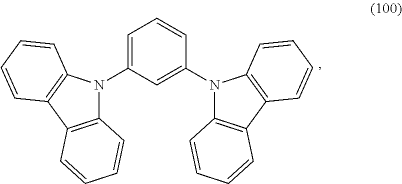 [SMILES: c1cc(-n2c3ccccc3c3ccccc32)cc(-n2c3ccccc3c3ccccc32)c1]
and
wherein the second carbazole derivative is selected from compounds represented by formulae (200) and (215):

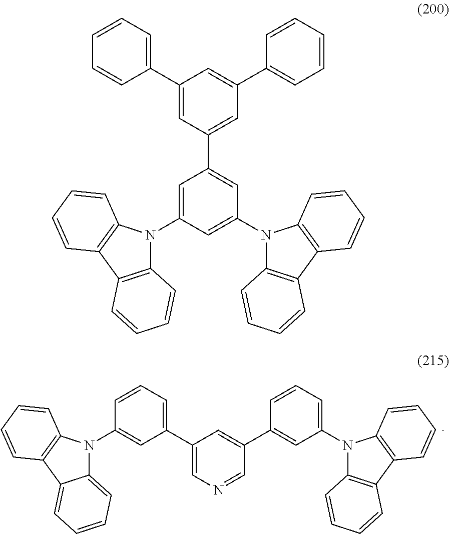 [SMILES: c1ccc(-c2cc(-c3ccccc3)cc(-c3cc(-n4c5ccccc5c5ccccc54)cc(-n4c5ccccc5c5ccccc54)c3)c2)cc1 ; c1cc(-c2cncc(-c3cccc(-n4c5ccccc5c5ccccc54)c3)c2)cc(-n2c3ccccc3c3ccccc32)c1]

9. An electronic device comprising the light-emitting device according to claim 1.

10. A lighting device comprising the light-emitting device according to claim 1.

11. A light-emitting device comprising:
an anode;
a hole-transport layer over the anode, the hole-transport layer comprising a first carbazole derivative;
a first light-emitting layer over the hole-transport layer, the first light-emitting layer comprising a second carbazole derivative and an emission substance dispersed in the second carbazole derivative;
a second light-emitting layer over the first light-emitting layer, the second light-emitting layer comprising the emission substance; and
a cathode over the second light-emitting layer,
wherein the first carbazole derivative consists of a first carbazole skeleton and a skeleton other than the first carbazole skeleton,
wherein the second carbazole derivative consists of a second carbazole skeleton and a skeleton other than the second carbazole skeleton,
wherein both a highest occupied molecular orbital and a lowest unoccupied molecular orbital of the first carbazole derivative are more widely spread over the first carbazole skeleton than the skeleton other than the first carbazole skeleton,
wherein a highest occupied molecular orbital of the second carbazole derivative is more widely spread over the second carbazole skeleton than the skeleton other than the second carbazole skeleton, and
wherein the lowest unoccupied molecular orbital of the second carbazole derivative is more widely spread over the skeleton other than the second carbazole skeleton than the second carbazole skeleton.

12. The light-emitting device according to claim 11, wherein the emission substance is a phosphorescent material.

13. The light-emitting device according to claim 11, wherein the emission substance is a blue emissive phosphorescent material.

14. The light-emitting device according to claim 11, wherein the skeleton other than the second carbazole skeleton of the second carbazole derivative comprises a skeleton having an electron-transport property.

15. The light-emitting device according to claim 14, wherein the skeleton having an electron-transport property is selected from an aromatic hydrocarbon group and a π-electron deficient heteroaromatic group.

16. The light-emitting device according to claim 11, wherein the first carbazole derivative is selected from compounds represented by formulae (100) to (107):

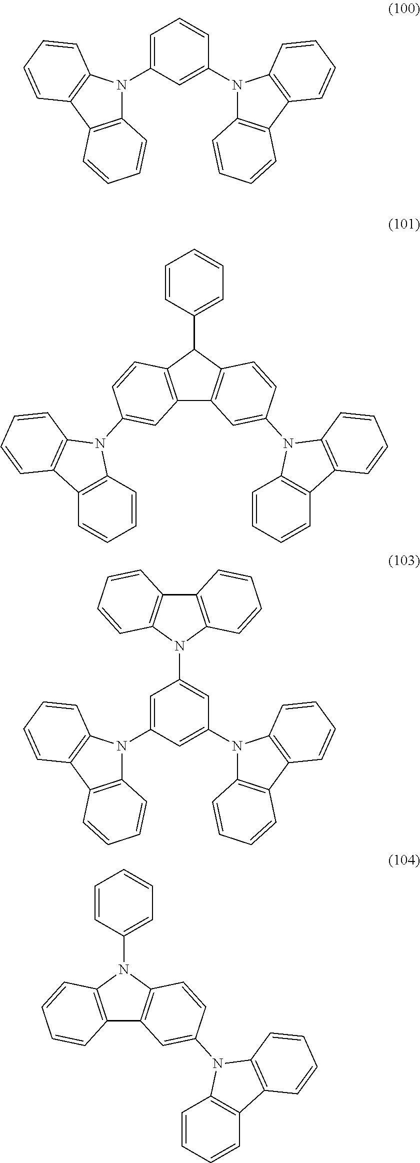

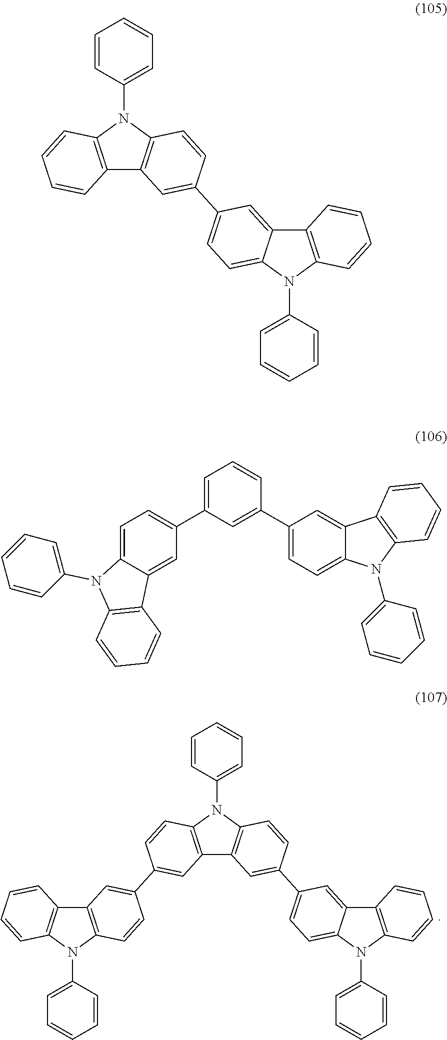 [SMILES: c1ccc(-n2c3ccccc3c3cc(-c4ccc5c(c4)c4ccccc4n5-c4ccccc4)ccc32)cc1 ; c1ccc(-n2c3ccccc3c3cc(-c4cccc(-c5ccc6c(c5)c5ccccc5n6-c5ccccc5)c4)ccc32)cc1 ; c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1]

17. The light-emitting device according to claim 11, wherein the second carbazole derivative is selected from compounds represented by formulae (200) to (220):

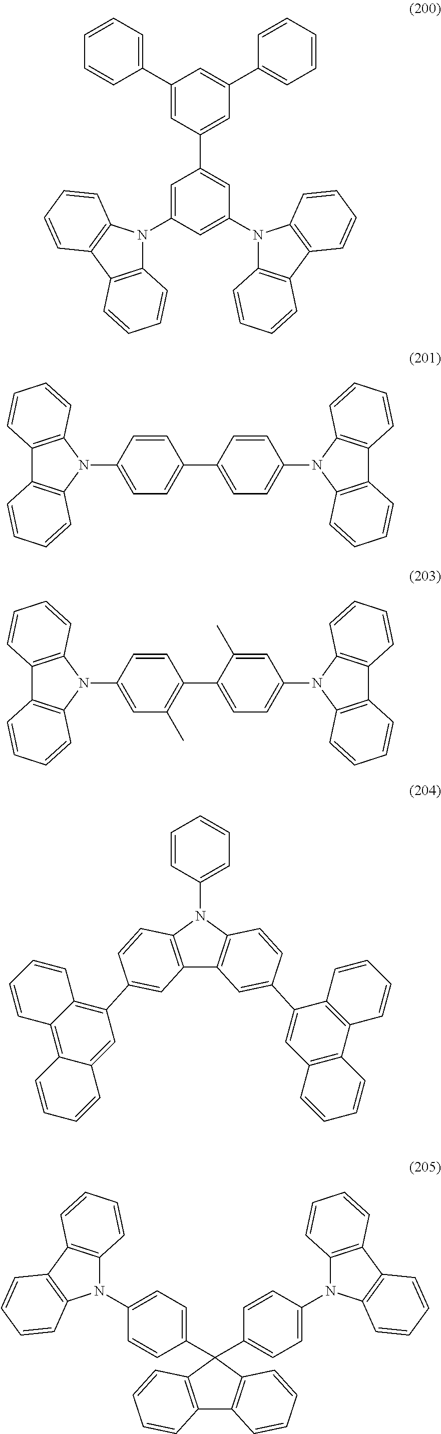 [SMILES: c1ccc(-c2cc(-c3ccccc3)cc(-c3cc(-n4c5ccccc5c5ccccc54)cc(-n4c5ccccc5c5ccccc54)c3)c2)cc1 ; c1ccc2c(c1)c1ccccc1n2-c1ccc(-c2ccc(-n3c4ccccc4c4ccccc43)cc2)cc1 ; Cc1cc(-n2c3ccccc3c3ccccc32)ccc1-c1ccc(-n2c3ccccc3c3ccccc32)cc1C ; c1ccc(-n2c3ccc(-c4cc5ccccc5c5ccccc45)cc3c3cc(-c4cc5ccccc5c5ccccc45)ccc32)cc1 ; c1ccc2c(c1)-c1ccccc1C2(c1ccc(-n2c3ccccc3c3ccccc32)cc1)c1ccc(-n2c3ccccc3c3ccccc32)cc1]

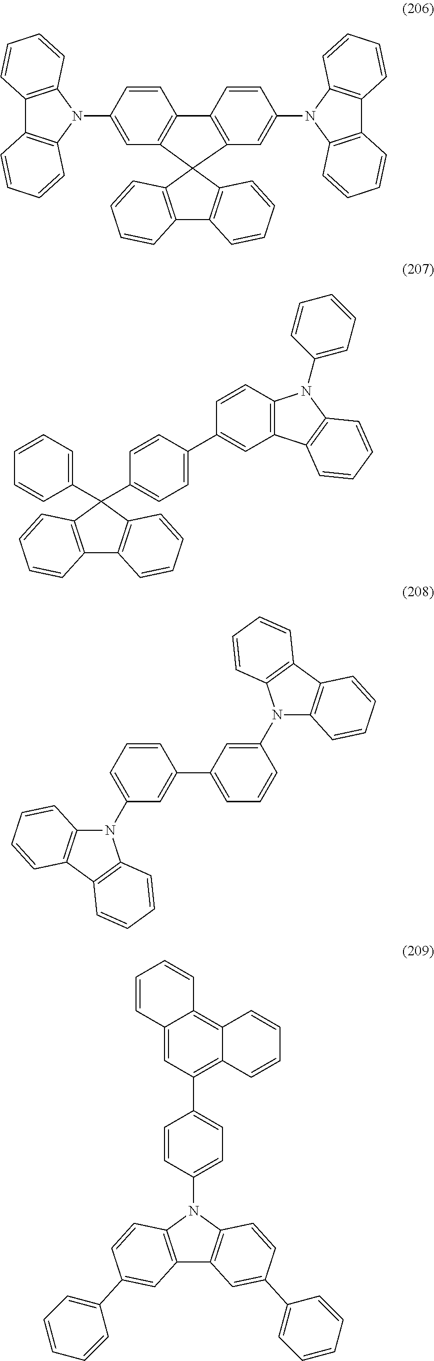 [SMILES: c1ccc2c(c1)-c1ccccc1C21c2cc(-n3c4ccccc4c4ccccc43)ccc2-c2ccc(-n3c4ccccc4c4ccccc43)cc21 ; c1ccc(-n2c3ccccc3c3cc(-c4ccc(C5(c6ccccc6)c6ccccc6-c6ccccc65)cc4)ccc32)cc1 ; c1cc(-c2cccc(-n3c4ccccc4c4ccccc43)c2)cc(-n2c3ccccc3c3ccccc32)c1 ; c1ccc(-c2ccc3c(c2)c2cc(-c4ccccc4)ccc2n3-c2ccc(-c3cc4ccccc4c4ccccc34)cc2)cc1]

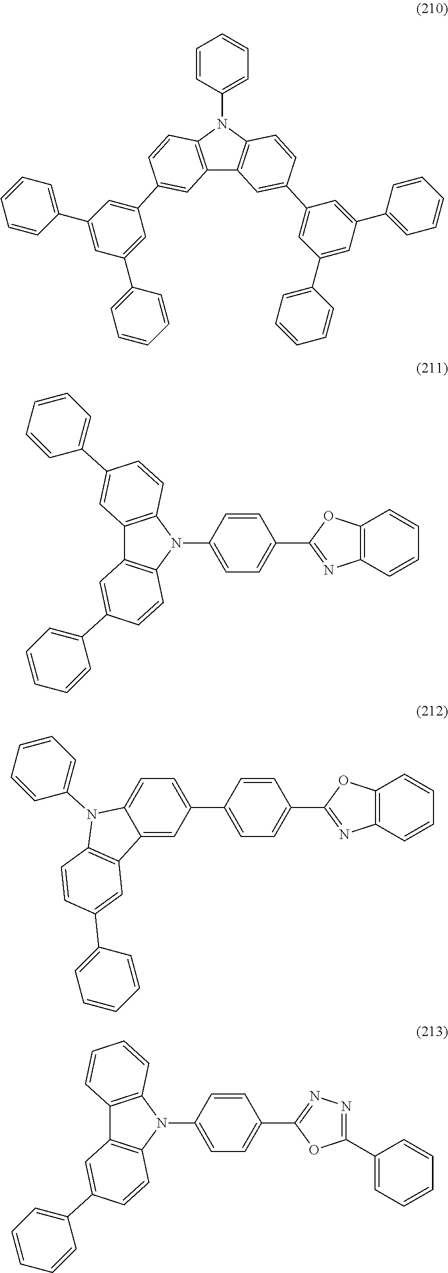

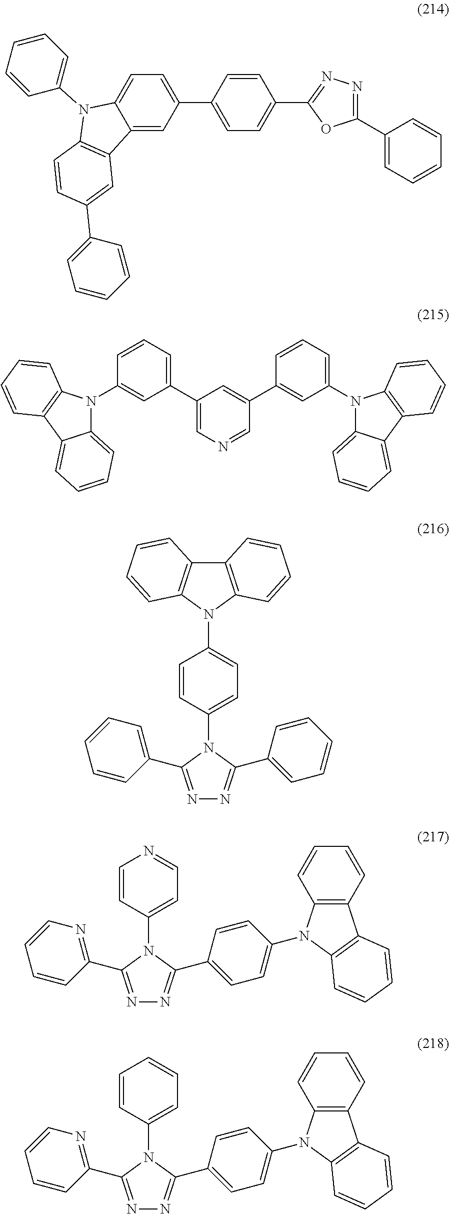

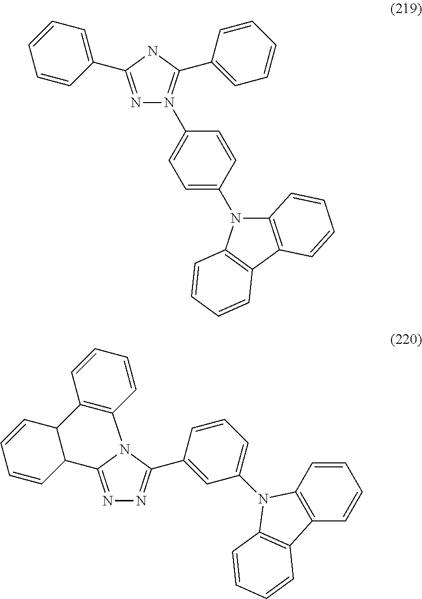

18. The light-emitting device according to claim 11,
wherein the first carbazole derivative is a compound represented by formula (100): 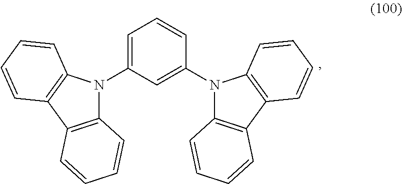 [SMILES: c1cc(-n2c3ccccc3c3ccccc32)cc(-n2c3ccccc3c3ccccc32)c1]
and
wherein the second carbazole derivative is selected from compounds represented by formula (200) and (215):

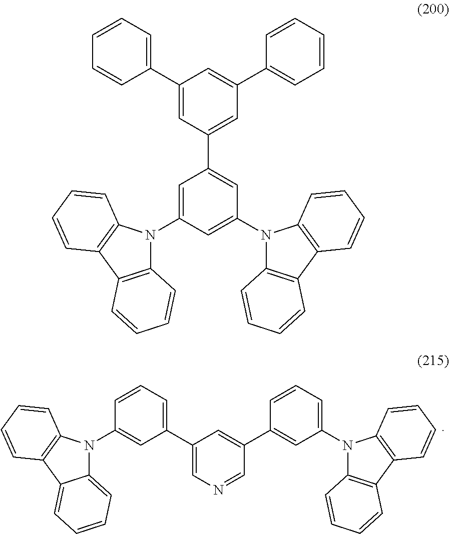 [SMILES: c1ccc(-c2cc(-c3ccccc3)cc(-c3cc(-n4c5ccccc5c5ccccc54)cc(-n4c5ccccc5c5ccccc54)c3)c2)cc1 ; c1cc(-c2cncc(-c3cccc(-n4c5ccccc5c5ccccc54)c3)c2)cc(-n2c3ccccc3c3ccccc32)c1]

19. An electronic device comprising the light-emitting device according to claim 11.

20. A lighting device comprising the light-emitting device according to claim 11.

21. A light-emitting device comprising:
an anode and a cathode; and
a layer comprising a carbazole derivative between the anode and the cathode,
wherein the carbazole derivative comprises a heteroaromatic group which is sandwiched by two carbazole groups.

22. The light-emitting device according to claim 21, wherein the heteroaromatic group is a pyridyl group.

23. The light-emitting device according to claim 21, wherein the carbazole derivative is represented by formula (215):

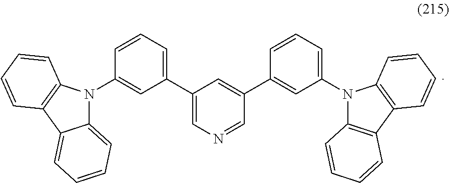 [SMILES: c1cc(-c2cncc(-c3cccc(-n4c5ccccc5c5ccccc54)c3)c2)cc(-n2c3ccccc3c3ccccc32)c1]

24. An electronic device comprising the light-emitting device according to claim 21.

25. A lighting device comprising the light-emitting device according to claim 21.
